(19) United States
(12) Patent Application Publication
(10) Pub. No.: US 2022/0214619 A1
(43) Pub. Date: Jul. 7, 2022

(54) PHOTORESIST TOPCOAT COMPOSITIONS AND PATTERN FORMATION METHODS

(71) Applicants: ROHM AND HAAS ELECTRONIC MATERIALS LLC, Marlborough, MA (US); DUPONT ELECTRONICS, INC., Wilmington, DE (US)

(72) Inventors: Joshua Kaitz, Shrewsbury, MA (US); Brian Malbrecht, London (CA); Deyan Wang, Hudson, MA (US); Michael Henry Howard, JR., Montchanin, DE (US)

(21) Appl. No.: 17/564,462

(22) Filed: Dec. 29, 2021

Related U.S. Application Data
(60) Provisional application No. 63/131,910, filed on Dec. 30, 2020.

(51) Int. Cl. G03F 7/11; G03F 7/32; G03F 7/40; G03F 7/20; G03F 7/004

(52) U.S. Cl. CPC G03F 7/11; G03F 7/322; G03F 7/0045; G03F 7/2006; G03F 7/40

(57) ABSTRACT

A topcoat composition, comprising a polymer comprising a repeating unit derived from one or more monomers of formula (1); and a solvent,

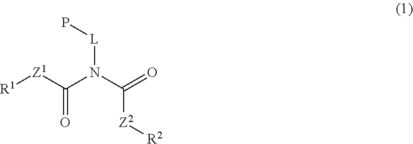

wherein Z¹, Z², R¹, R², and L are as described herein, and P is a polymerizable group.

### FIELD

The present invention relates to photoresist topcoat compositions that may be applied above a photoresist composition. The invention finds particular applicability to topcoat layers in an immersion lithography process for the formation of semiconductor devices.

### BACKGROUND

Photoresist materials are photosensitive compositions typically used for transferring an image to one or more underlying layers such as a metal, semiconductor or dielectric layer disposed on a semiconductor substrate. To increase the integration density of semiconductor devices and allow for the formation of structures having dimensions in the nanometer range, photoresists and photolithography processing tools having high-resolution capabilities have been and continue to be developed.

One approach to achieving nanometer (nm)-scale feature sizes in semiconductor devices is the use of short wavelengths of light, for example, 193 nm or less, during photoresist exposure. To further improve lithographic performance, immersion lithography tools have been developed to effectively increase the numerical aperture (NA) of the lens of the imaging device, for example, a scanner having a KrF (248 nm) or ArF (193 nm) light source. This is accomplished by use of a high refractive index fluid, typically water, between the last surface of the imaging device and the upper surface of the semiconductor wafer. ArF immersion tools are currently pushing the boundaries of lithography to dimensions below 40 nm with the use of multiple (double or higher order) patterning.

In immersion lithography, direct contact between the immersion fluid and the photoresist layer can result in leaching of components from the photoresist into the immersion fluid. This leaching may contaminate the optical lens and alter the effective refractive index and transmission properties of the immersion fluid. In an effort to address the problem of inhibiting the migration of photoresist material into the immersion fluid, photoresist topcoat layers have been introduced as barrier layers between the immersion fluid and the underlying photoresist layer. Preferably, the topcoat layer is not soluble in the immersion liquid, is transparent to light at the exposure wavelengths, and does not intermix with the photoresist layer. In addition, it is preferable for the topcoat layer to readily dissolve in a basic developer, such that the topcoat layer and the photoresist layer may be removed simultaneously.

Increases in hydrophobicity at the immersion fluid interface are typically achieved through the use of a fluorinated polymer. The use of highly hydrophobic materials may negatively impact particular defect types, for example, coating and patterning defects. Such defects can prevent proper formation of resist patterns and pattern transfer to underlying layers, thereby negatively impacting device yield. These defects may take the form, for example, of one or more of micro-bridging, missing contact holes, line pinching, or CD shift. A topcoat layer having a balance of good hydrophobicity and low coating and patterning defectivity levels would therefore be desired.

There is a continuing need in the art for improved photoresist topcoat compositions that address one or more problems associated with the state of the art.

### SUMMARY

Provided is a topcoat composition comprising a polymer including a repeating unit derived from one or more monomers of formula (1); and a solvent,

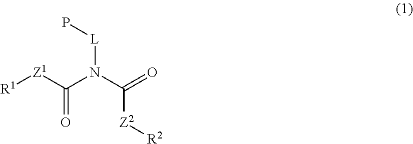

wherein, in formula (1), Z¹ and Z² are each independently a single bond or a divalent linking group comprising one or more of substituted or unsubstituted C₁₋₃₀ alkylene, substituted or unsubstituted C₁₋₃₀ heteroalkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted C₁₋₃₀ heteroarylene, —O—, —C(O)—, —N(R³)—, —S—, or —S(O)₂—, wherein R³ is hydrogen, substituted or unsubstituted C₁₋₃₀ alkyl, substituted or unsubstituted C₃₋₃₀ cycloalkyl, substituted or unsubstituted C₂₋₃₀ heterocycloalkyl, substituted or unsubstituted C₆₋₃₀ aryl, substituted or unsubstituted C₇₋₃₀ arylalkyl, substituted or unsubstituted C₁₋₃₀ heteroaryl, or substituted or unsubstituted C₂₋₃₀ heteroarylalkyl, optionally, Z¹ and Z² together form a ring via a single bond or a double bond between Z¹ and Z², R¹ and R² are each independently substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, substituted or unsubstituted C₂₋₃₀ alkylheteroaryl, —OR⁴, or —N(R⁵)₂, wherein R⁴ and R⁵ are each independently substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₂₀ heterocycloalkyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl, optionally, R¹ and R² together form a ring via a single bond or a divalent linking group, L is a single bond or a multivalent linking group, optionally, L is a multivalent linking group further comprising an additional group of the formula:

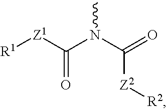

and
P is a polymerizable group.

Also provided is a coated substrate comprising a photoresist layer on a substrate; and a topcoat layer formed on the photoresist layer, wherein the topcoat layer is derived from the inventive topcoat composition.

Further provided is a pattern formation method comprising forming a photoresist layer over a substrate; forming a topcoat layer over the photoresist layer, wherein the topcoat layer is formed from the inventive topcoat composition; pattern-wise exposing the topcoat layer and the photoresist layer to activating radiation; and contacting the exposed topcoat layer and the exposed photoresist layer with a developer to form a resist pattern.

### DETAILED DESCRIPTION

Reference will now be made in detail to exemplary embodiments, examples of which are illustrated in the present description. In this regard, the present exemplary embodiments may have different forms and should not be construed as being limited to the descriptions set forth herein. Accordingly, the exemplary embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

As used herein, the terms “a,” “an,” and “the” do not denote a limitation of quantity and are to be construed to cover both the singular and the plural, unless otherwise indicated herein or clearly contradicted by context. “Or” means “and/or” unless clearly indicated otherwise. The modifier “about” used in connection with a quantity is inclusive of the stated value and has the meaning dictated by the context (e.g., includes the degree of error associated with measurement of the particular quantity). All ranges disclosed herein are inclusive of the endpoints, and the endpoints are independently combinable with each other. The suffix “(s)” is intended to include both the singular and the plural of the term that it modifies, thereby including at least one of that term. “Optional” or “optionally” means that the subsequently described event or circumstance can or cannot occur, and that the description includes instances where the event occurs and instances where it does not. The terms “first,” “second,” and the like, herein do not denote an order, quantity, or importance, but rather are used to distinguish one element from another. When an element is referred to as being “on” another element, it may be directly in contact with the other element or intervening elements may be present therebetween. In contrast, when an element is referred to as being “directly on” another element, there are no intervening elements present. It is to be understood that the described components, elements, limitations, and/or features of aspects may be combined in any suitable manner in the various aspects.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, the term “hydrocarbon group” refers to an organic compound having at least one carbon atom and at least one hydrogen atom, optionally substituted with one or more substituents where indicated; “alkyl group” refers to a straight or branched chain saturated hydrocarbon having the specified number of carbon atoms and having a valence of one; “alkylene group” refers to an alkyl group having a valence of two; “hydroxyalkyl group” refers to an alkyl group substituted with at least one hydroxyl group (—OH); “alkoxy group” refers to “alkyl-O-”; “carboxylic acid group” refers to a group having the formula “—C(═O)—OH”; “cycloalkyl group” refers to a monovalent group having one or more saturated rings in which all ring members are carbon; “cycloalkylene group” refers to a cycloalkyl group having a valence of two; “alkenyl group” refers to a straight or branched chain, monovalent hydrocarbon group having at least one carbon-carbon double bond; “alkenoxy group” refers to “alkenyl-O-”; “alkenylene group” refers to an alkenyl group having a valence of two; “cycloalkenyl group” refers to a non-aromatic cyclic hydrocarbon group having at least three carbon atoms, with at least one carbon-carbon double bond; “alkynyl group” refers to a monovalent hydrocarbon group having at least one carbon-carbon triple bond; the term “aromatic group” refers to a monocyclic or polycyclic ring system that satisfies the Huckel Rule and includes carbon atoms in the ring, and optionally may include one or more heteroatoms selected from N, O, and S instead of a carbon atom in the ring; “aryl group” refers to a monovalent aromatic monocyclic or polycyclic ring system where every ring member is carbon, and may include a group with an aromatic ring fused to at least one cycloalkyl or heterocycloalkyl ring; “arylene group” refers to an aryl group having a valence of two; “alkylaryl group” refers to an aryl group that has been substituted with an alkyl group; “arylalkyl group” refers to an alkyl group that has been substituted with an aryl group; “aryloxy group” refers to “aryl-O-”; and “arylthio group” refers to “aryl-S-”.

The prefix “hetero” means that the compound or group includes at least one member that is a heteroatom (e.g., 1, 2, 3, or 4 or more heteroatom(s)) instead of a carbon atom, wherein the heteroatom(s) is each independently N, O, S, Si, or P; “heteroatom-containing group” refers to a substituent group that includes at least one heteroatom; “heteroalkyl group” refers to an alkyl group having 1-4 or more heteroatoms instead of carbon; “heterocycloalkyl group” refers to a cycloalkyl group having 1-4 or more heteroatoms as ring members instead of carbon; “heterocycloalkylene group” refers to a heterocycloalkyl group having a valence of two; “heteroaryl group” refers to an aryl group having 1-4 or more heteroatoms as ring members instead of carbon; and “heteroarylene group” refers to an heteroaryl group having a valence of two.

The term “halogen” means a monovalent substituent that is fluorine (fluoro), chlorine (chloro), bromine (bromo), or iodine (iodo). The prefix “halo” means a group including one more of a fluoro, chloro, bromo, or iodo substituent instead of a hydrogen atom. A combination of halo groups (e.g., bromo and fluoro), or only fluoro groups may be present.

“Fluorinated” shall be understood to mean having one or more fluorine atoms incorporated into the group. For example, where a C₁₋₁₈ fluoroalkyl group is indicated, the fluoroalkyl group can include one or more fluorine atoms, for example, a single fluorine atom, two fluorine atoms (e.g., as a 1,1-difluoroethyl group), three fluorine atoms (e.g., as a 2,2,2-trifluoroethyl group), or fluorine atoms at each free valence of carbon (e.g., as a perfluorinated group such as CF₃, C₂F₅, C₃F₇, or C₄F₉). A “substituted fluoroalkyl group” shall be understood to mean a fluoroalkyl group that is further substituted by an additional substituent group.

As used herein, an “acid-labile group” refers to a group in which a bond is cleaved by the catalytic action of an acid, optionally and typically with thermal treatment, resulting in a polar group, such as a carboxylic acid or alcohol group, being formed on the polymer, and optionally and typically with a moiety connected to the cleaved bond becoming disconnected from the polymer. Such acid is typically a photo-generated acid with bond cleavage occurring during post-exposure baking. Suitable acid-labile groups include, for example: tertiary alkyl ester groups, secondary or tertiary aryl ester groups, secondary or tertiary ester groups having a combination of alkyl and aryl groups, tertiary alkoxy groups, secondary or tertiary ether groups, acetal groups, or ketal groups. Acid-labile groups are also commonly referred to in the art as “acid-cleavable groups,” “acid-cleavable protecting groups,” “acid-labile protecting groups,” “acid-leaving groups,” “acid-decomposable groups,” and “acid-sensitive groups.”

As used herein, the term “immersion fluid” means a fluid, typically water, interposed between a lens of an exposure tool and a photoresist-coated substrate to conduct immersion lithography.

“Substituted” means that at least one hydrogen atom on the group is replaced with another group, provided that the designated atom's normal valence is not exceeded. When the substituent is oxo (i.e., ═O), then two hydrogens on the carbon atom are replaced. Combinations of substituents or variables are permissible. Exemplary groups that may be present on a “substituted” position include, but are not limited to, nitro (—NO2), cyano (—CN), hydroxy (—OH), oxo (═O), amino (—NH₂), mono-or di-(C₁₋₆)alkylamino, alkanoyl (such as a C₂₋₆ alkanoyl group such as acyl), formyl (—C(═O)H), carboxylic acid or an alkali metal or ammonium salt thereof; esters (including acrylates, methacrylates, and lactones) such as C₂₋₆ alkyl esters (—C(═O)O-alkyl or —OC(═O)-alkyl) and C₇₋₁₃ aryl esters (—C(═O)O-aryl or —OC(═O)-aryl); amido (—C(═O)NR₂ wherein R is hydrogen or C₁₋₆ alkyl), carboxamido (—CH₂C(═O)NR₂ wherein R is hydrogen or C₁₋₆ alkyl), halogen, thiol (—SH), C₁₋₆ alkylthio (—S-alkyl), thiocyano (—SCN), C₁₋₆ alkyl, C₂₋₆ alkenyl, C₂₋₆ alkynyl, C₁₋₆ haloalkyl, C₁₋₉ alkoxy, C₁₋₆ haloalkoxy, C₃₋₁₂ cycloalkyl, C₅₋₁₈ cycloalkenyl, C₆₋₁₂ aryl having at least one aromatic ring (e.g., phenyl, biphenyl, naphthyl, or the like, each ring either substituted or unsubstituted aromatic), C₇₋₁₉ arylalkyl having 1 to 3 separate or fused rings and from 6 to 18 ring carbon atoms, arylalkoxy having 1 to 3 separate or fused rings and from 6 to 18 ring carbon atoms, C₇₋₁₂ alkylaryl, C₂₋₁₂ heterocycloalkyl, C₁₋₁₂ heteroaryl, C₁₋₆ alkyl sulfonyl (—S(═O)₂-alkyl), C₆₋₁₂ arylsulfonyl (—S(═O)₂-aryl), or tosyl (CH₃C₆H₄SO₂—). When a group is substituted, the indicated number of carbon atoms is the total number of carbon atoms in the group, excluding those of any substituents. For example, the group —CH₂CH₂CN is a C₂ alkyl group substituted with a cyano group.

The topcoat compositions of the invention comprise a matrix polymer, a surface active polymer, and a solvent mixture, and can include one or more additional, optional components. Preferred topcoat compositions of the invention that are applied above a photoresist layer can minimize or prevent migration of components of the photoresist layer into an immersion fluid employed in an immersion lithography process. In preferred topcoat compositions of the invention, the surface active polymer is self-segregating. As used herein, the term “immersion fluid” means a fluid, typically water, interposed between a lens of an exposure tool and a photoresist coated substrate to conduct immersion lithography.

As used herein, a topcoat layer will be considered as inhibiting the migration of photoresist material into an immersion fluid if a decreased amount of acid or organic material is detected in the immersion fluid upon use of the topcoat composition relative to the same photoresist system that is processed in the same manner, but in the absence of the topcoat composition layer. Detection of photoresist material in the immersion fluid can be conducted through mass spectrometry (MS) of the immersion fluid before exposure of the photoresist (with and without the overcoated topcoat composition layer) and then after lithographic processing of the photoresist layer (with and without the overcoated topcoat composition layer) with exposure through the immersion fluid. Typically, the topcoat composition provides at least a 10% reduction in photoresist material (e.g., acid or organics as detected by MS) residing in the immersion fluid relative to the same photoresist that does not include the topcoat layer (i.e., the immersion fluid directly contacts the photoresist layer), more preferably the topcoat composition provides at least a 20%, or 50%, or 90%, or 99%, or 100% reduction in the amount of photoresist material in the immersion fluid relative to the amount of photoresist material in the immersion fluid for a same photoresist that does not include the topcoat layer.

Preferred topcoat compositions of the invention can allow for improvement in one or more of various water contact angle characteristics that are important in an immersion lithography process, for example, static contact angle, receding contact angle, advancing contact angle and sliding angle at the immersion fluid interface. The topcoat compositions provide topcoat layers having excellent developer solubility for both exposed and unexposed regions of the layer, for example, in an aqueous base developer. Preferred topcoat compositions can exhibit beneficial pattern defect levels.

The compositions can be used in dry lithography or more typically in immersion lithography processes. In addition, the compositions can be beneficial from the standpoint of minimizing or preventing the occurrence of outgassing, which can be deleterious in view of void formation and/or the generation of defects. The exposure wavelength is not particularly limited except by the photoresist compositions, with wavelengths of less than 300 nm, for example, 248 nm, 193 nm or an EUV wavelength (e.g., 13.4 nm) being typical. Use of the compositions in a 193 nm immersion lithography process is particularly preferred.

Polymers useful in the invention are aqueous alkali soluble such that a topcoat layer formed from the composition can be removed in the resist development step using an aqueous alkaline developer, for example, a quaternary ammonium hydroxide solution, for example, tetra methyl ammonium hydroxide (TMAH), typically 0.26 N aqueous TMAH. The different polymers suitably may be present in varying relative amounts.

A variety of polymers may be employed in the topcoat compositions of the invention, including polymers comprising polymerized acrylate groups, polyesters, or other repeat units and/or polymer backbone structures such as provided by, for example, poly(alkylene oxide), poly(meth)acrylic acid, poly (meth)acrylamides, polymerized aromatic (meth)acrylates, and polymerized vinyl aromatic monomers. Typically, the polymers include at least two different repeat units. The different polymers suitably may be present in varying relative amounts.

The polymers of the topcoat compositions of the invention may contain a variety of repeat units, including, for example, one or more: hydrophobic groups; weak acid groups; strong acid groups; branched optionally substituted alkyl or cycloalkyl groups; fluoroalkyl groups; or polar groups, such as ester, ether, carboxy, or sulfonyl groups. The presence of particular functional groups on the repeat units of the polymers will depend, for example, on the intended functionality of the polymer.

In certain preferred aspects, one or more polymers of the coating composition will comprise one or more groups that are reactive during lithographic processing, for example, one or more photoacid-acid labile groups that can undergo cleavage reactions in the presence of acid and heat, such as acid-labile ester groups (e.g., t-butyl ester groups such as provided by polymerization of t-butyl acrylate or t-butylmethacrylate, adamantylacrylate) and/or acetal groups such as provided by polymerization of a vinyl ether compound. The presence of such groups can render the associated polymer(s) more soluble in a developer solution, thereby aiding in developability and removal of the topcoat layer during a development process.

The polymers can advantageously be chosen to tailor characteristics of the topcoat layer, with each generally serving one or more purpose or function. Such functions include, for example, one or more of photoresist profile adjusting, topcoat surface adjusting, reducing defects and reducing interfacial mixing between the topcoat and photoresist layers.

The topcoat compositions include one or more, preferably two or more with two being typical, matrix polymers that may include one or more different types of repeat units, with two or three different repeat units being typical. The matrix polymer should provide a sufficiently high developer dissolution rate for reducing overall defectivity due, for example, to micro-bridging. The matrix polymer may include, for example, a sulfonamide-containing monomer for enhancing the polymer developer dissolution rate. A typical developer dissolution rate for the matrix polymer is greater than 300 nm/second, preferably greater than 500 nm/second, more preferably greater than 1000 nm/second, even more preferably greater than 3000 nm/second. The matrix polymers can be fluorinated or non-fluorinated. For some photoresist materials, fluorinated topcoat matrix polymers can reduce or minimize interfacial mixing between the topcoat layer and underlying photoresist layer. Accordingly, one or more repeating unit of the matrix polymer can be fluorinated, for example, with a fluoroalkyl group such as a C₁₋₄ fluoroalkyl group, typically fluoromethyl, and may be present, for example, as a sulfonamide group (e.g., —NHSO₂CF₃) or a fluoroalcohol group (e.g., —C(CF₃)₂OH).

The matrix polymer has a higher surface energy than that of, and is preferably immiscible with, the surface active polymer, to allow the surface active polymer to phase separate from the matrix polymer and migrate to the upper surface of the topcoat layer away from the topcoat photoresist interface. The surface energy of the matrix polymer is typically from 30 to 60 millinewtons per meter (mN/m).

Exemplary monomers of formulas (I) and (II) may be used to prepare the matrix polymer, however, other monomers may also be used as described herein and as commonly used in the art.

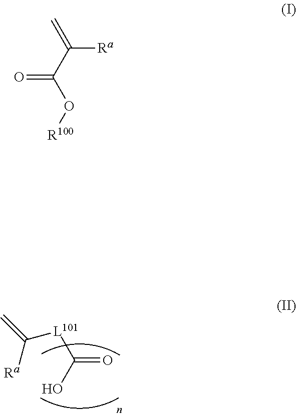

In formulas (I) and (II), R^{a} is hydrogen, fluorine, cyano, a substituted or unsubstituted C₁₋₁₀ alkyl, or a substituted or unsubstituted C₁₋₁₀ fluoroalkyl, typically H or methyl.

In formula (I), R¹⁰⁰ represents substituted or unsubstituted C₁₋₁₀₀ or C₁₋₂₀ alkyl, typically C₁₋₁₂ alkyl; substituted or unsubstituted C₃₋₃₀ or C₃₋₂₀ cycloalkyl; or a substituted or unsubstituted poly(C₁₋₃alkylene oxide). Preferably, the substituted C₁₋₁₀₀ or C₁₋₂₀ alkyl, the substituted C₃₋₃₀ or C₃₋₂₀ cycloalkyl, and the substituted poly(C₁₋₃ alkylene oxide) are substituted with one or more of a halogen, a fluoroalkyl group such as a C₁₋₄ fluoroalkyl group, typically fluoromethyl, a sulfonamide group —NH—S(O)₂—Y¹ where Y¹ is F or C₁₋₄ perfluoroalkyl (e.g., —NHSO₂CF₃), or a fluoroalcohol group (e.g., —C(CF₃)₂OH).

In formula (II), L¹⁰¹ represents a single bond or a multivalent linking group chosen, for example, from optionally substituted aliphatic, such as C₁₋₆ alkylene or C₃₋₂₀ cycloalkylene, and aromatic hydrocarbons, and combinations thereof, optionally with one or more linking moieties chosen from —O—, —S—, —C(O)—, and —NR¹⁰²— wherein R¹⁰² is chosen from hydrogen and optionally substituted C₁₋₁₀ alkyl; and n is an integer from 1 to 5, typically 1. For example, the matrix polymer can include a repeating unit derived from one or more monomers of formula (II) wherein L¹⁰¹ is a single bond or a multivalent linking group selected from substituted or unsubstituted C₁₋₂₀ alkylene, typically C₁₋₆ alkylene; substituted or unsubstituted C₃₋₂₀ cycloalkylene; typically C₃₋₁₀ cycloalkylene; and substituted or unsubstituted C₆₋₂₄ arylene, and n is 1, 2, or 3.

It is believed that units derived from monomers of formula (I) allow for good solubility of the matrix polymer in the solvent used in the topcoat composition. Due to their highly polar nature, units derived from monomers of formula (II) can impart desirable solubility characteristics to the matrix polymer in an aqueous base developer. This allows for effective removal during photoresist development.

Units of general formula (I) are typically present in the matrix polymer in an amount from 0 to 100 mol %, more typically from 20 to 80 mol % or from 30 to 70 mol %, based on total polymerized units of the matrix polymer. Units of general formula (II) are typically present in the matrix polymer in an amount from 0 to 50 mol %, more typically, from 5 to 40 mol % or from 15 to 30 mol %, based on total polymerized units of the matrix polymer.

Non-limiting examples of monomers for the units of general formula (I) include the following:

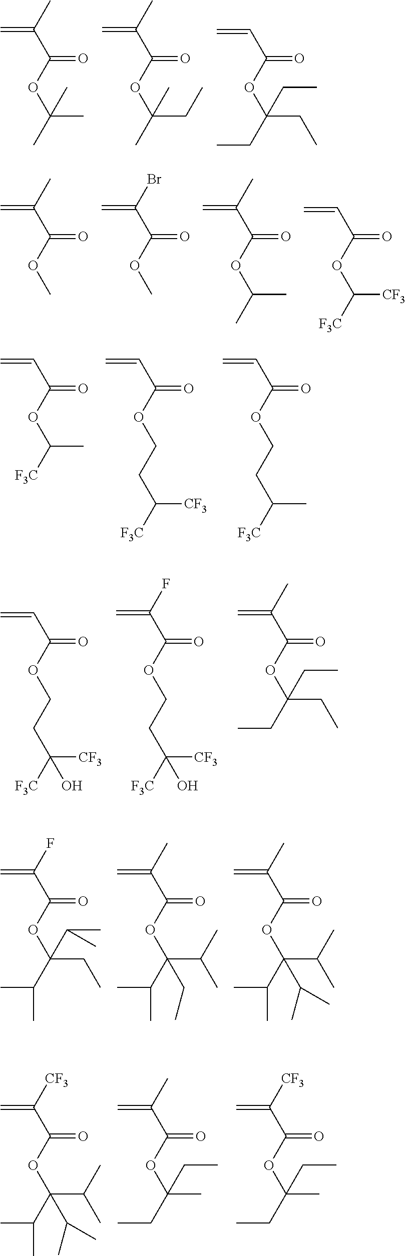

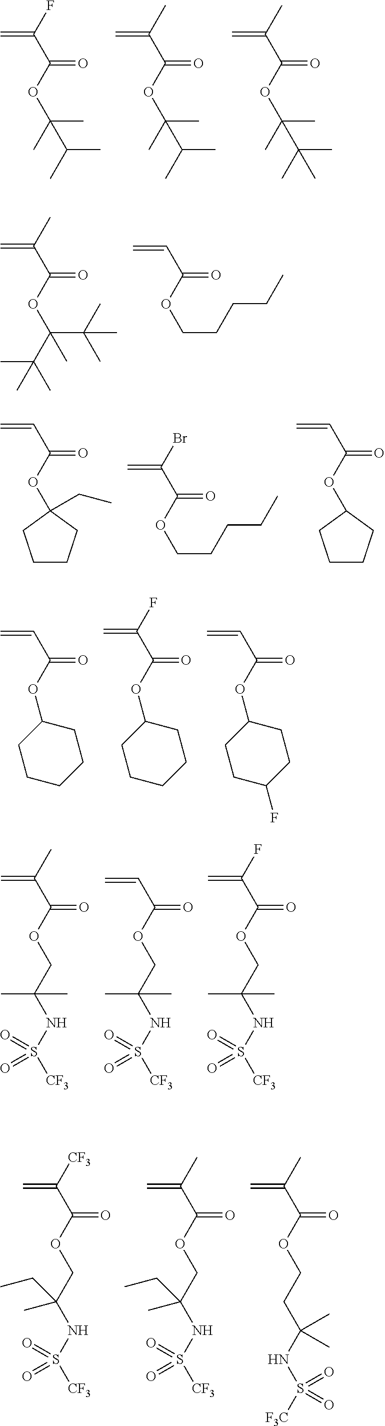

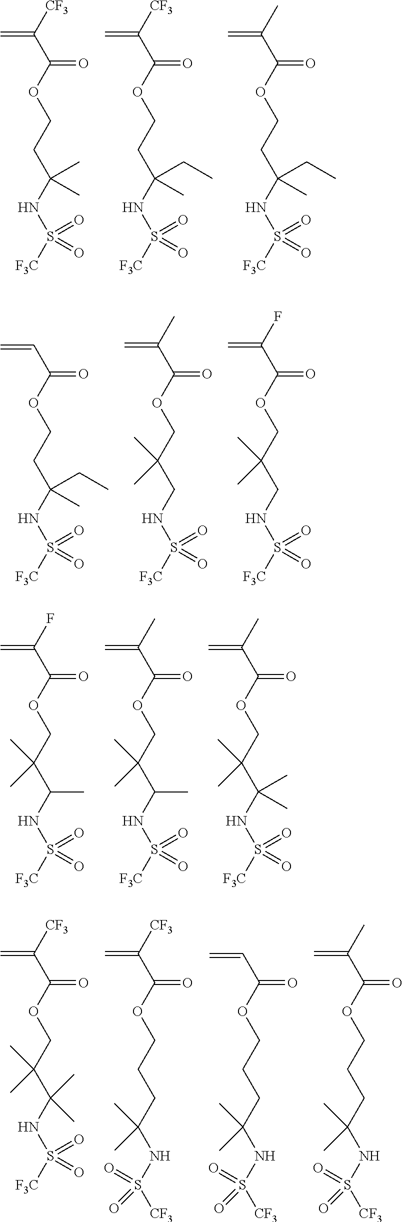

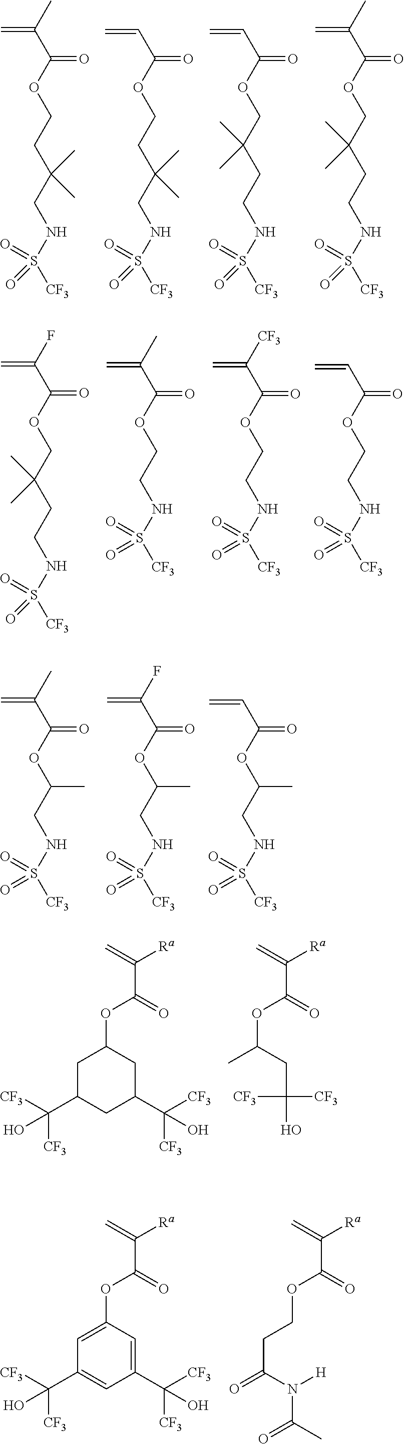

Non-limiting examples of monomers for the units of general formula (II) include the following:

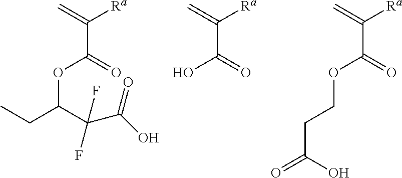

wherein R^{a} is as defined above.

Other exemplary matrix polymers can be prepared from monomers such as (alkyl)acrylates, preferably an acid-labile (alkyl)acrylate, such as t-butyl acrylate, t-butyl methacrylate, methyladamantyl acrylate, methyladamantyl methacrylate, ethylfenchyl acrylate, ethylfenchyl methacrylate, and the like, and other non-cyclic alkyl and alicyclic (alkyl)acrylates. Other suitable matrix polymers include, for example, those which contain polymerized units of a non-aromatic cyclic olefin (endocyclic double bond) such as an optionally substituted norborene, those that contain polymerized anhydride units, particularly polymerized maleic anhydride and/or itaconic anhydride units, and those containing a vinylic group, such as styrenes.

Non-limiting examples of matrix polymers include the following:

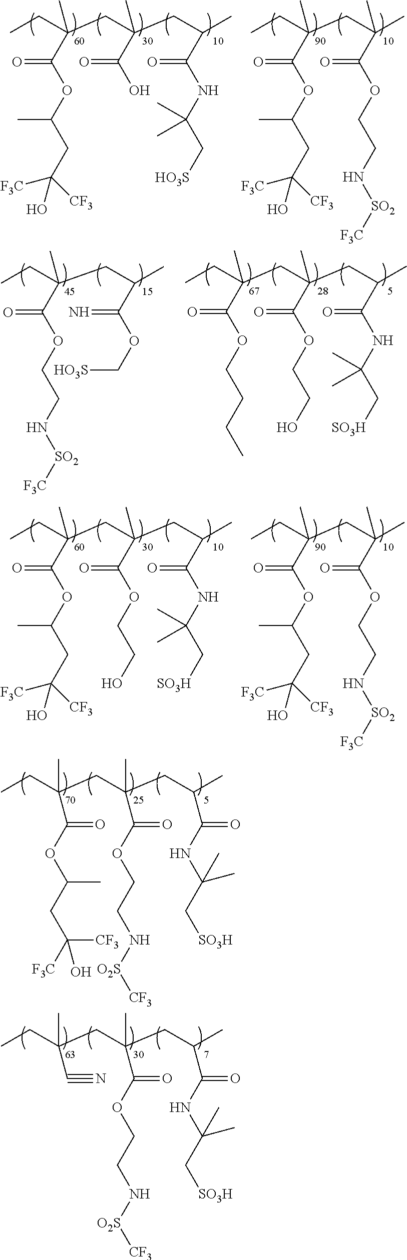

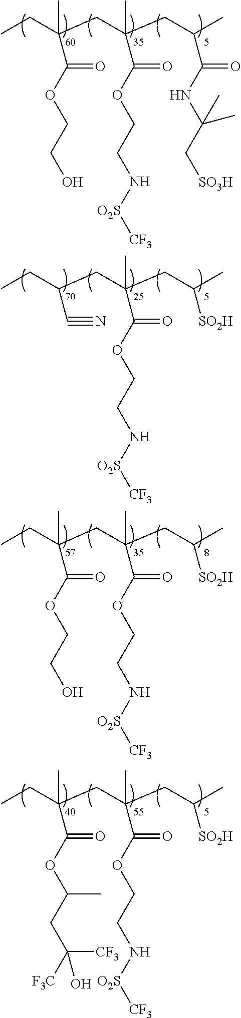

Non-limiting examples of matrix polymers further include the following:

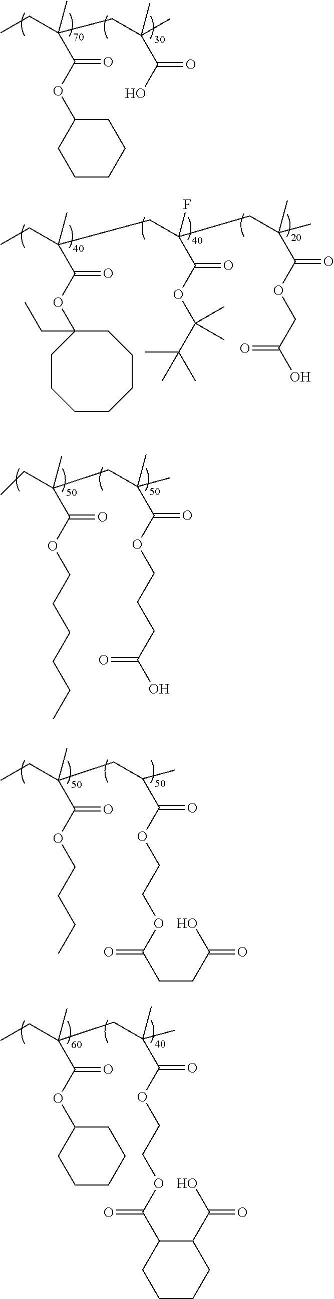

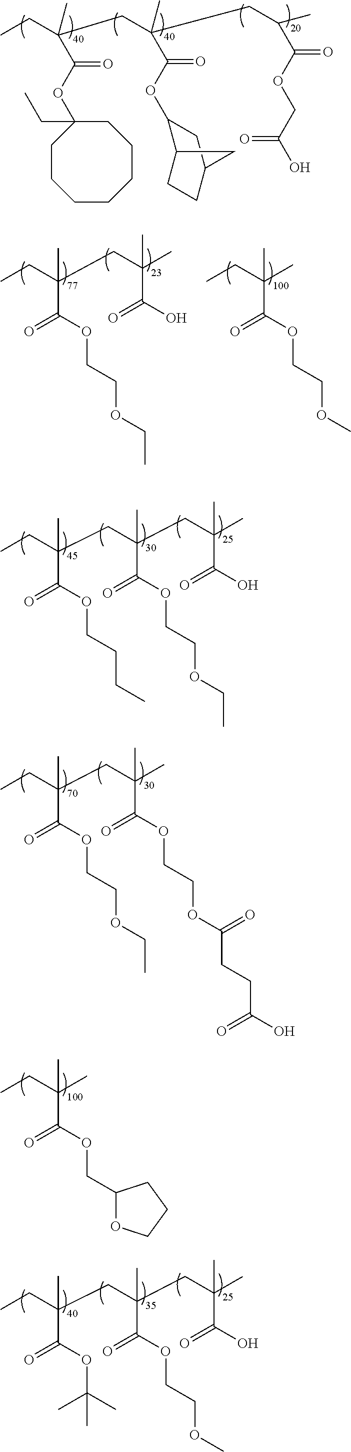

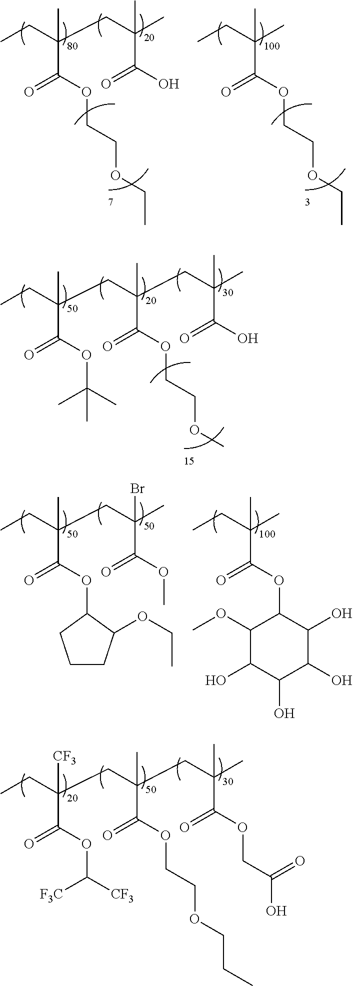

The one or more matrix polymers are typically present in the compositions in a combined amount of from 70 to 99.9 wt %, or 70 to 99 wt %, more typically from 85 to 95 wt %, based on total solids of the topcoat composition. The weight average molecular weight (Mw) of the matrix polymer is typically less than 400,000 Dalton (Da), for example, from 1000 to 50,000 Da, from 2000 to 25,000 Da, or from 5000 to 25,000 Da.

The surface active polymer is provided in the topcoat compositions to provide beneficial surface properties at the topcoat/immersion fluid interface. In particular, the surface active polymer beneficially can provide desirable surface properties with respect to water, for example, one or more of improved static contact angle (SCA), receding contact angle (RCA), advancing contact angle (ACA) or sliding angle (SA) at the topcoat/immersion fluid interface. In particular, the surface active polymer can allow for a higher RCA, which can allow for faster scanning speeds and increased process throughput. A layer of the topcoat composition in a dried state typically has a water receding contact angle of from 60 to 95°, typically from 75 to 93°, from 75 to 85° or from 75 to 80°. The phrase “in a dried state” means containing 8 wt % or less of solvent, based on the entire composition.

The surface active polymer is preferably aqueous alkali soluble. The surface active polymer preferably has a lower surface energy than the matrix polymer. Preferably, the surface active polymer has a significantly lower surface energy than and is substantially immiscible with the matrix polymer, as well as any other polymers present in the topcoat composition. In this way, the topcoat composition can be self-segregating, wherein the surface active polymer migrates to the upper surface of the topcoat layer apart from other polymers during coating. The resulting topcoat layer is thereby rich in the surface active polymer at the topcoat layer upper surface which, in the case of an immersion lithography process is at the topcoat/immersion fluid interface in the case of an immersion lithography process

While the desired surface energy of the surface active polymer will depend on the selected matrix polymer and its surface energy, the surface active polymer surface energy is typically from 15 to 35 mN/m, preferably from 18 to 30 mN/m. The surface energy of the surface active polymer is typically from 5 to 25 mN/m less than that of the matrix polymer, preferably from 5 to 15 mN/m less than that of the matrix polymer.

Suitable polymerized units for the surface active polymer include, for example, those containing one or more group chosen from acid labile, base labile, sulfonamide, alkyl, and ester groups. Preferably, such acid labile, base labile, sulfonamide, alkyl and ester groups are fluorinated.

Exemplary surface active polymers can include, for example, those which comprise a repeat unit derived from a monomer of formula (III), a monomer of formula (IV), or a combination thereof:

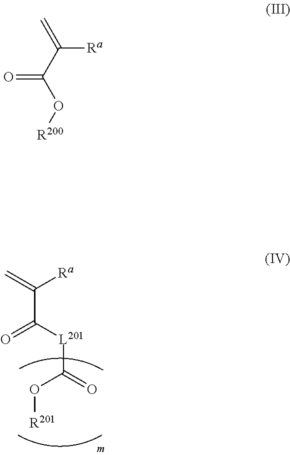

wherein, in formulas (III) and (IV), each Ra independently represents hydrogen, halogen, C₁₋₃ alkyl, typically H or methyl; R²⁰⁰ represents substituted or unsubstituted C₁₋₁₀₀ or C₁₋₂₀ alkyl, typically C₁₋₁₂ alkyl; substituted or unsubstituted C₃₋₃₀ or C₃₋₂₀ cycloalkyl; or a substituted or unsubstituted poly(C₁₋₃ alkylene oxide); and R²⁰¹ represents linear, branched or cyclic C₁₋₂₀ fluoroalkyl, typically C₁₋₁₂ fluoroalkyl. Preferably, the substituted C₁₋₁₀₀ or C₁₋₂₀ alkyl, the substituted C₃₋₃₀ or C₃₋₂₀ cycloalkyl, and the substituted poly(C₁₋₃ alkylene oxide) are substituted with one or more of a halogen, a fluoroalkyl group such as a C_{1- 4} fluoroalkyl group, typically fluoromethyl, a sulfonamide group —NH—S(O)₂—Y¹ where Y¹ is F or C₁₋₄ perfluoroalkyl (e.g., —NHSO₂CF₃), or a fluoroalcohol group (e.g., —C(CF₃)₂OH).

L²⁰¹ represents a single bond or a multivalent linking group chosen, for example, from optionally substituted aliphatic, such as C₁₋₆ alkylene or C₃₋₂₀ cycloalkylene, and aromatic hydrocarbons, and combinations thereof, optionally with one or more linking moieties chosen from —O—, —S—, —C(O)—, and —NR¹⁰²— wherein R¹⁰² is chosen from hydrogen and optionally substituted C₁₋₁₀ alkyl; and m is an integer of from 1 to 5, typically 1. For example, the matrix polymer can include a repeating unit derived from one or more monomers of formula (IV) wherein L²⁰¹ is a single bond or a multivalent linking group selected from substituted or unsubstituted C₁₋₂₀ alkylene, typically C₁₋₆ alkylene; substituted or unsubstituted C₃₋₂₀ cycloalkylene; typically C₃₋₁₀ cycloalkylene; and substituted or unsubstituted C₆₋₂₄ arylene, and m is 1, 2, or 3.

Exemplary monomers of formula (III) include those described above for formula (I). Units derived from monomers of formula (III) are believed to allow for effective phase separation of the surface active polymer from other polymers in the composition, enhanced dynamic contact angles, for example, increased receding angle and decreased sliding angle. It is believed that units derived from monomers of formula (IV) contribute to phase separation and to enhanced dynamic contact angle properties, as well as imparting to the surface active polymer beneficial hysteresis characteristics and improved solubility in an aqueous base developer.

Units of general formula (III) are typically present in the surface active polymer in an amount of from 0 to 90 mol %, for example, from 10 to 40 mol %, based on total repeat units of the surface active polymer. Units of general formula (IV) are typically present in the surface active polymer in an amount of from 0 to 90 mol %, for example, from 50 to 80 mol %, based on total repeat units of the surface active polymer.

Non-limiting examples of repeat units for use in the surface active polymer include polymerized units of one or more of the following monomers:

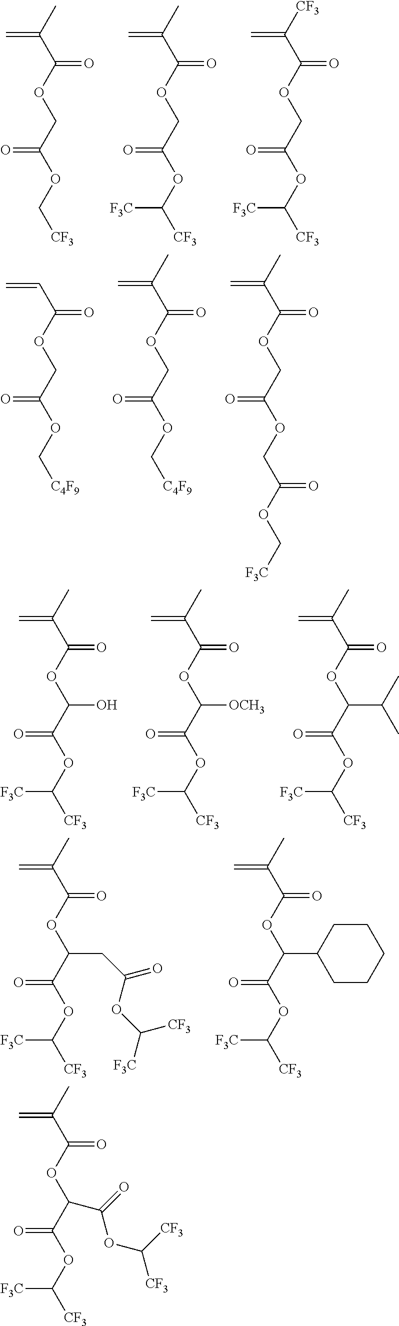

The surface active polymer may include one or more additional type of unit. The surface active polymer can, for example, include one or more additional units comprising a fluorine-containing group, such as a fluorinated sulfonamide group, a fluorinated alcohol group, a fluorinated ester group, or a combination thereof, or an acid labile leaving group, or a combination thereof. Fluoroalcohol group-containing units can be present in the surface active polymer for purposes of enhancing developer solubility, or to allow for enhanced dynamic contact angles, for example, increased receding angle and decreased sliding angle, and for improving developer affinity and solubility. Additional types of units, if used, are typically present in the surface active polymer in an amount of from 1 to 70 mol % based on the surface active polymer.

The surface active polymer lower limit for immersion lithography is generally dictated by the need to prevent leaching of the photoresist components. The surface active polymer is present in the compositions in an amount of from 0.1 to 30 wt %, more typically from 3 to 20 wt % or 5 to 15 wt %, based on total solids of the topcoat composition. The surface active polymer lower limit for immersion lithography is generally dictated by the need to prevent leaching of the photoresist components. The weight average molecular weight M_{w} of the additive polymer is typically less than 400,000 Da, preferably from 5000 to 50,000 Da, more preferably from 5000 to 25,000 Da.

The topcoat compositions include a polymer comprising a repeating unit derived from one or more monomers of formula (1):

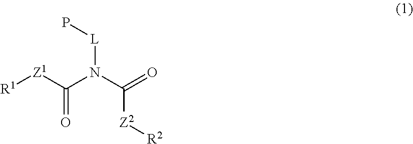

wherein, Z¹ and Z² are each independently a single bond or a divalent linking group comprising one or more of substituted or unsubstituted C₁₋₃₀ alkylene, substituted or unsubstituted C₁₋₃₀ heteroalkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted C₁₋₃₀ heteroarylene, —O—, —C(O)—, —N(R³)—, —S—, or —S(O)₂—, wherein R³ is hydrogen, substituted or unsubstituted C₁₋₃₀ alkyl, substituted or unsubstituted C₃₋₃₀ cycloalkyl, substituted or unsubstituted C₂₋₃₀ heterocycloalkyl, substituted or unsubstituted C₆₋₃₀ aryl, substituted or unsubstituted C₇₋₃₀ arylalkyl, substituted or unsubstituted C₁₋₃₀ heteroaryl, or substituted or unsubstituted C₂₋₃₀ heteroarylalkyl. Optionally, Z¹ and Z² together form a ring via a single bond or a double bond between Z¹ and Z².

In formula (1), R¹ and R² may be each independently substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, substituted or unsubstituted C₂₋₃₀ alkylheteroaryl, —OR⁴, or —N(R⁵)₂, wherein R⁴ and R⁵ are each independently substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₂₀ heterocycloalkyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl. Optionally, R¹ and R² together form a ring via a single bond or a divalent linking group comprising one or more of substituted or unsubstituted C₁₋₃₀ alkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted divalent C₇₋₃₀ arylalkyl, substituted or unsubstituted C₁₋₃₀ heteroarylene, or substituted or unsubstituted divalent C₂₋₃₀ heteroarylalkyl, —O—, —C(O)—, —C(O)—O—, —C(O)—N(R²a)—, —S—, —S(O)₂—, or —N(R₂ₐ)—S(O)₂— wherein R^{2a} is hydrogen, straight chain or branched C₁₋₂₀ alkyl, monocyclic or polycyclic C₃₋₂₀ cycloalkyl, or monocyclic or polycyclic C₂₋₂₀ heterocycloalkyl.

In formula (1), L is a single bond or a multivalent linking group such as a divalent, trivalent, or tetravalent linking group. For example, L can be a single bond or a divalent linking group chosen from one or more of substituted or unsubstituted C₁₋₃₀ alkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted divalent C₇₋₃₀ arylalkyl, substituted or unsubstituted C₁₋₃₀ heteroarylene, or substituted or unsubstituted divalent C₂₋₃₀ heteroarylalkyl, —O—, —C(O)—, —C(O)—O—, —C(O)—N(R^{2b})—, —S—, —S(O)₂—, or —N(R^{2b})—S(O)₂-wherein R^{2b} is hydrogen, straight chain or branched C₁₋₂₀ alkyl, monocyclic or polycyclic C₃₋₂₀ cycloalkyl, or monocyclic or polycyclic C₂₋₂₀ heterocycloalkyl.

In formula (1), P is a polymerizable group. Typically, the polymerizable group is chosen from (meth)acrylic, vinyl, and norbornyl.

In formula (1), L is optionally a divalent linking group further comprising an additional group of the formula:

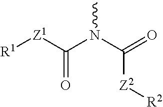

wherein Z¹, Z², R¹, and R² are as described above.

In some embodiments, the polymer may include a repeating unit derived from one or more monomers of formula (1a):

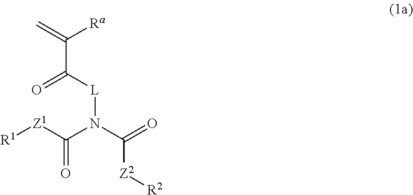

In formula (1a), R^{a} hydrogen, fluorine, cyano, a substituted or unsubstituted C₁₋₁₀ alkyl, or a substituted or unsubstituted C₁₋₁₀ fluoroalkyl. L is as defined for formula (1). For example, L is a single bond or a divalent linking group including one or more groups chosen from substituted or unsubstituted C₁₋₃₀ alkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted C₁₋₃₀ heteroarylene, —O—, —C(O)—, —C(O)O—, —OC(O)—, —N(R²⁵)—, —S—, or —S(O)₂—, wherein R²⁵ is hydrogen, a straight chain or branched C₁₋₂₀ alkyl, monocyclic or polycyclic C₃₋₂₀ cycloalkyl, or monocyclic or polycyclic C₂₋₂₀ heterocycloalkyl.

In formula (1a), Z¹ and Z² are the same, wherein Z¹ and Z² are chosen from a single bond, —O—, a divalent linking group comprising a group of the formula —C(O)—, or a divalent linking group comprising a group of the formula —C(O)—O—. R¹ and R² are each independently substituted or unsubstituted C₁₋₃₀ alkyl; and optionally, R¹ and R² together form a ring via a single bond or a divalent linking group.

Non-limiting examples of the monomers of formula (1) and/or (1a) include:

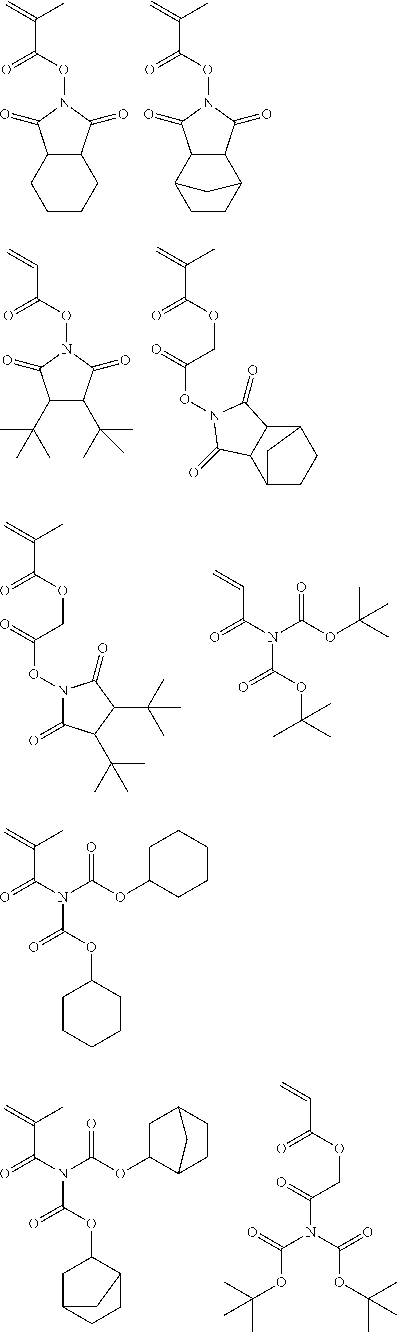

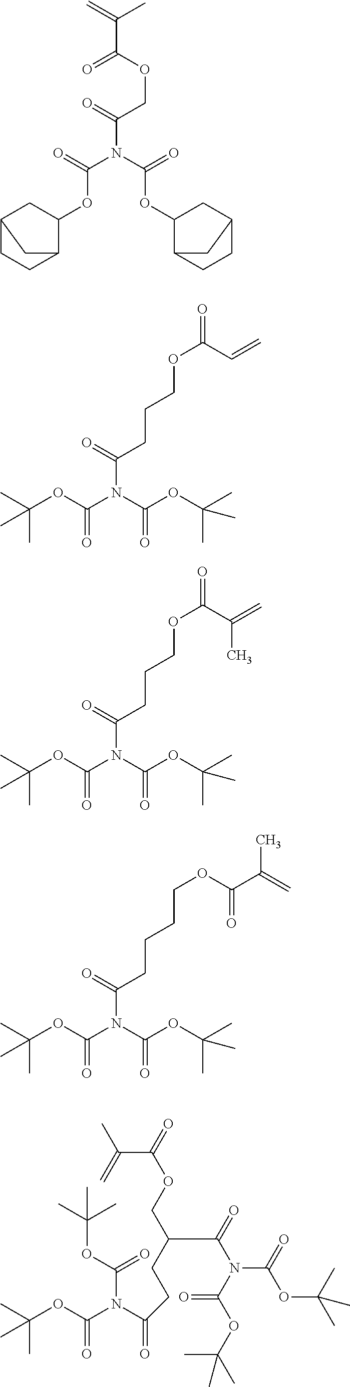

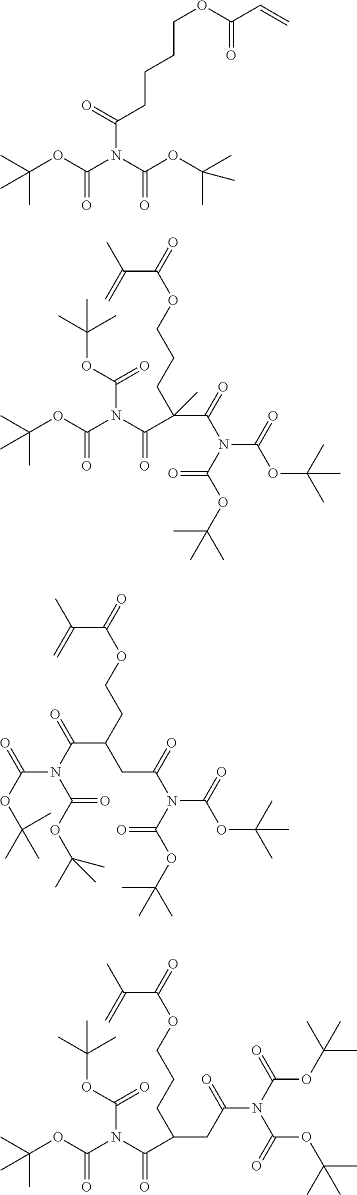

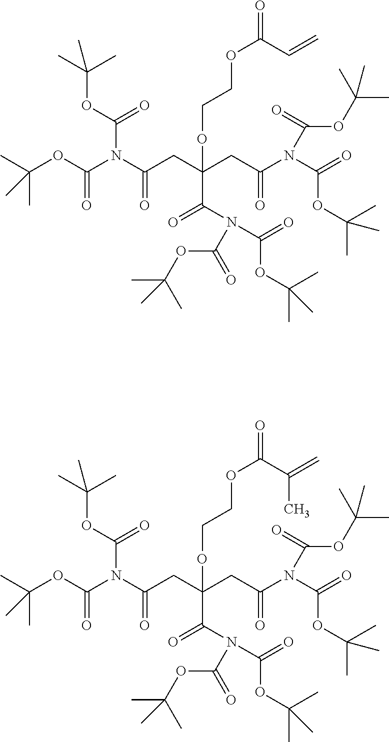

The monomers above that include a single di(Boc) amide moiety may be referred to as a single-armed monomer. Other exemplary monomers include more than one di(Boc)amide moiety and may be referred to as double-armed monomers. For a polymer comprising a structural unit derived from the single-armed monomer, one carboxyl functional group may be generated on the structural unit derived from the single-armed monomer upon hydrolysis. For a polymer comprising a structural unit derived from the double-armed monomer, two carboxyl functional groups may be generated for each structural unit derived from the double-armed monomer upon hydrolysis. Similarly, for a polymer comprising a structural unit derived from the triple-armed monomer, three carboxyl functional groups may be generated for each structural unit derived from the triple-armed monomer upon hydrolysis. This can be beneficial for making the polymer more hydrophilic upon contacting an aqueous alkaline developer.

The inventive polymer may optionally further include one or more additional repeating units different from the repeating unit derived from the one or more monomers of formula (1). The inventive polymer may be a matrix polymer or a surface active polymer, and the polymer may further include one or more additional repeating units derived, for example, from any one or more of the monomers of general formulas (I), (II), (III), and (IV) described in conjunction with the matrix polymers and the surface active polymers. The one or more additional units if present in the polymer may be used in an amount of up to 90 mol %, and typically from 3 to 50 mol %, based on total moles of repeating units in the polymer.

In certain preferred aspects, polymers may comprise one or more groups that are reactive during lithographic processing, for example, one or more photoacid-acid labile groups that can undergo cleavage reactions in the presence of acid and heat, such as acid-labile ester groups (e.g., t-butyl ester groups such as provided by polymerization of t-butyl acrylate or t-butylmethacrylate, 2-methyl-2-adamantylmethacrylate) and/or acetal groups such as provided by polymerization of 1-butoxyethylmethacrylate. The presence of such groups can render the associated polymer(s) more soluble in a developer solution, thereby aiding in developability and removal of the topcoat layer during a development process.

For example, the inventive polymer may include an acid-labile repeating unit that is derived from one or more monomers of formulae (2a), (2b), (2c), (2d), or (2e):

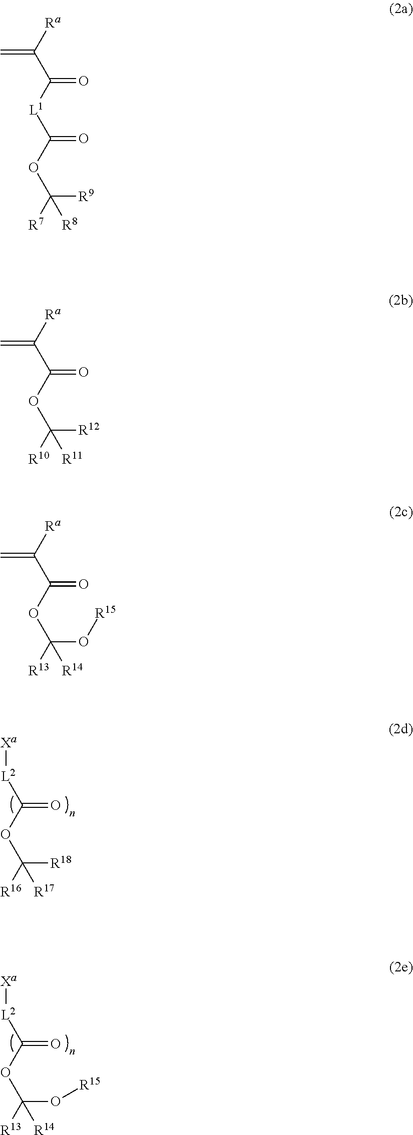

In formulae (2a) to (2e), R^{a} is hydrogen, fluorine, cyano, a substituted or unsubstituted C₁₋₁₀ alkyl, or a substituted or unsubstituted C₁₋₁₀ fluoroalkyl. Preferably, Ra is hydrogen, fluorine, or substituted or unsubstituted C₁₋₅ alkyl, typically methyl.

In formula (2a), L¹ is a divalent linking group including at least one carbon atom, at least one heteroatom, or a combination thereof. For example, L¹ may include 1 to 10 carbon atoms and at least one heteroatom. In a typical example, L¹ may be —OCH₂—, —OCH₂CH₂O— or —N(R^{1a})—, wherein R^{1a} is hydrogen or C₁₋₆ alkyl.

In formulae (2a) and (2b), R⁷ to R¹² are each independently hydrogen, straight chain or branched C₁₋₂₀ alkyl, a monocyclic or polycyclic C₃₋₂₀ cycloalkyl, a monocyclic or polycyclic C₂₋₂₀ heterocycloalkyl, a straight chain or branched C₂₋₂₀ alkenyl, a monocyclic or polycyclic C₃₋₂₀ cycloalkenyl, a monocyclic or polycyclic C₃₋₂₀ heterocycloalkenyl, a monocyclic or polycyclic C₆₋₂₀ aryl, or a monocyclic or polycyclic C₁₋₂₀ heteroaryl, each of which is substituted or unsubstituted; provided that only one of R⁷ to R⁹ can be hydrogen and only one of R¹⁰ to R¹² can be hydrogen. Preferably, R⁷ to R¹² are each independently a straight chain or branched C₁₋₆ alkyl, or a monocyclic or polycyclic C₃₋₁₀ cycloalkyl, each of which is substituted or unsubstituted.

In formula (2a), any two of R⁷ to R⁹ together optionally may form a ring, and each of R⁷ to R⁹ optionally may further include as part of their structure one or more groups selected from —O—, —C(O)—, —C(O)—O—, —S—, —S(O)₂—, and N(R¹⁹)—S(O)₂—, wherein R¹⁹ is hydrogen, a straight chain or branched C₁₋₂₀ alkyl, monocyclic or polycyclic C₃₋₂₀ cycloalkyl, or monocyclic or polycyclic C₂₋₂₀ heterocycloalkyl. In formula (2b), any two of le° to R¹² together optionally may form a ring, and each of R¹⁰ to R¹² optionally may further include as part of their structure one or more groups selected from —O—, —C(O)—, —C(O)—O—, —S—, —S(O)₂—, and N(R²⁰)—S(O)₂—, wherein R²⁰ is hydrogen, a straight chain or branched C₁₋₂₀ alkyl, monocyclic or polycyclic C₃₋₂₀ cycloalkyl, or monocyclic or polycyclic C₂₋₂₀ heterocycloalkyl. For example, any one or more of R⁷ to R¹² can be independently a group of the formula —CH₂C(═O)CH₍₃₋ₙ₎Yₙ, where each Y is independently a substituted or unsubstituted C₂₋₁₀ heterocycloalkyl and n is 1 or 2. For example, each Y may be independently a substituted or unsubstituted C₂₋₁₀ heterocycloalkyl including a group of the formula —O(C^{a1})(C^{a2})O—, wherein C^{a1} and C^{a2} are each independently hydrogen or a substituted or unsubstituted alkyl, and where C^{a1} and C^{a2} together optionally form a ring.

In formula (2c) and (2e), R¹³ to R¹⁴ may be each independently hydrogen, straight chain or branched C₁₋₂₀ alkyl, a monocyclic or polycyclic C₃₋₂₀ cycloalkyl, a monocyclic or polycyclic C₂₋₂₀ heterocycloalkyl, a monocyclic or polycyclic C₆₋₂₀ aryl, or a monocyclic or polycyclic C₁₋₂₀ heteroaryl, each of which is substituted or unsubstituted; and R¹⁵ is straight chain or branched C₁₋₂₀ alkyl, monocyclic or polycyclic C₃₋₂₀ cycloalkyl, or monocyclic or polycyclic C₂₋₂₀ heterocycloalkyl, each of which is substituted or unsubstituted. Optionally, one of R¹³ or R¹⁴ together with R¹⁵ forms a heterocyclic ring. Preferably, R¹³ and R¹⁴ may be each independently hydrogen, straight chain or branched C₁₋₂₀ alkyl, monocyclic or polycyclic C₃₋₂₀ cycloalkyl, or monocyclic or polycyclic C₂₋₂₀ heterocycloalkyl.

In formula (2d), R¹⁶ to R¹⁸ may be each independently straight chain or branched C₁₋₂₀ alkyl, a monocyclic or polycyclic C₃₋₂₀ cycloalkyl, a monocyclic or polycyclic C₂₋₂₀ heterocycloalkyl, a monocyclic or polycyclic C₆₋₂₀ aryl, or a monocyclic or polycyclic C₁₋₂₀ heteroaryl, each of which is substituted or unsubstituted, any two of R¹⁶ to R¹⁸ together optionally form a ring, and each of R¹⁶ to R¹⁸ optionally may include as part of their structure one or more groups selected from —O—, —C(O)—, —C(O)—O—, —S—, —S(O)₂—, and —N(R^{1b})—S(O)₂—, wherein R^{1b} may be hydrogen, a straight chain or branched C₁₋₂₀ alkyl, monocyclic or polycyclic C₃₋₂₀ cycloalkyl, or monocyclic or polycyclic C₂₋₂₀ heterocycloalkyl; X^{a} is a polymerizable group selected from vinyl and norbornyl.

In formulae (2d) and (2e), each L² is a single bond or a divalent linking group, provided that L² is not a single bond when X^{a} is vinyl. Preferably, L² is a monocyclic or polycyclic C₆₋₃₀ arylene or a monocyclic or polycyclic C₆₋₃₀ cycloalkylene, each of which can be substituted or unsubstituted. In formulae (2d) and (2e), n is 0 or 1. It is to be understood that when n is 0, the L² group is connected directly to the oxygen atom.

Non-limiting examples of monomers (2a) include:

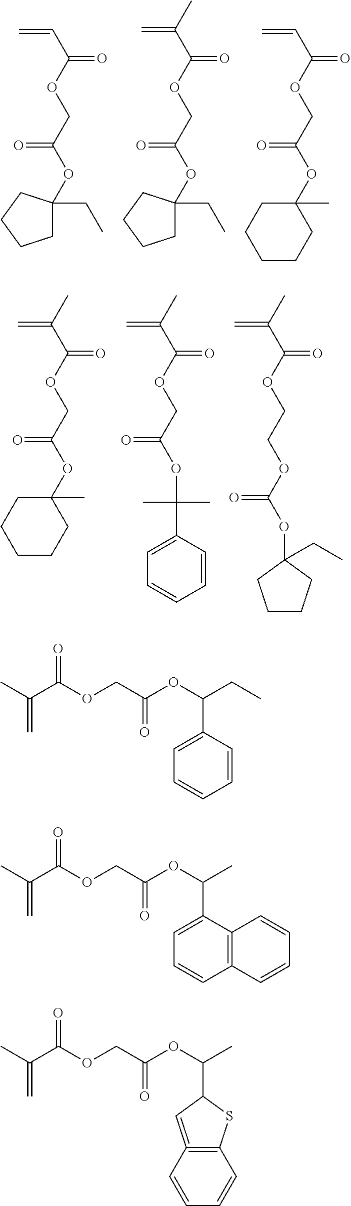

Non-limiting examples of monomers of formula (2b) include:

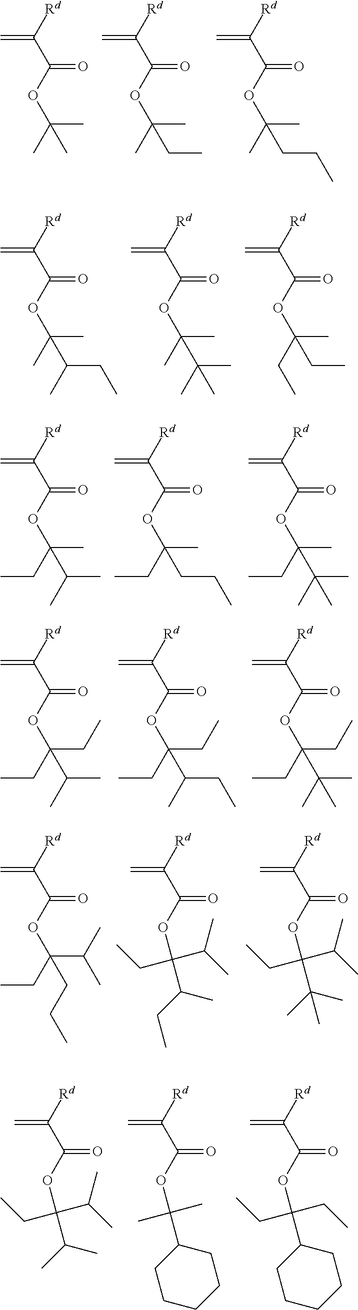

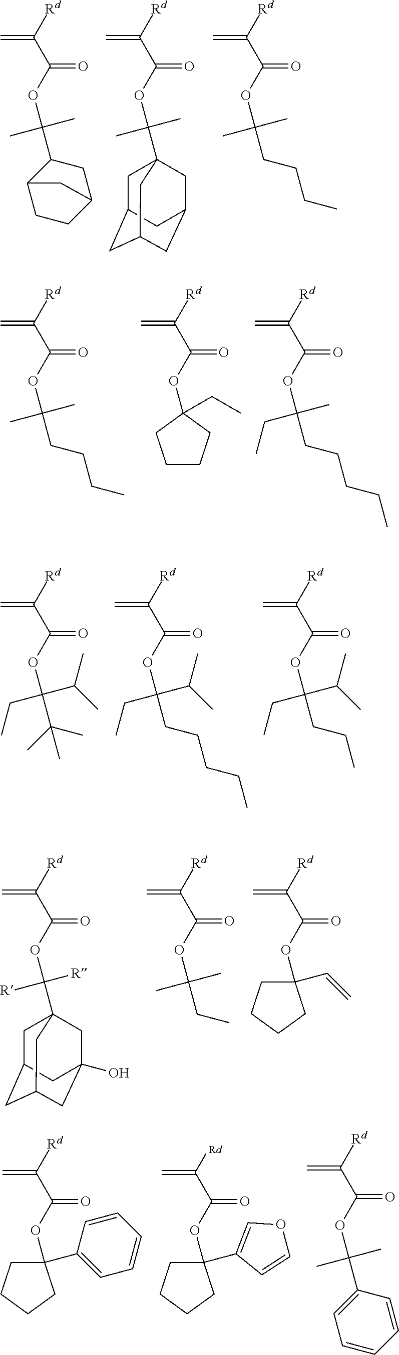

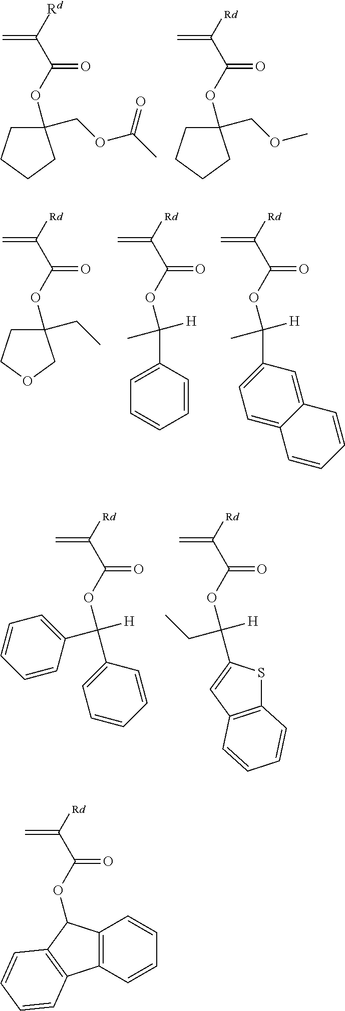

wherein R^{d} is as defined above for R^{a}; and R′ and R″ are each independently a straight chain or branched C₁₋₂₀ alkyl, a monocyclic or polycyclic C₃₋₂₀ cycloalkyl, a monocyclic or polycyclic C₂₋₂₀ heterocycloalkyl, a straight chain or branched C₂₋₂₀ alkenyl, a monocyclic or polycyclic C₃₋₂₀ cycloalkenyl, a monocyclic or polycyclic C₃₋₂₀ heterocycloalkenyl, a monocyclic or polycyclic C₆₋₂₀ aryl, or a monocyclic or polycyclic C₁₋₂₀ heteroaryl, each of which is substituted or unsubstituted.

Non-limiting examples of monomers of formula (2c) include:

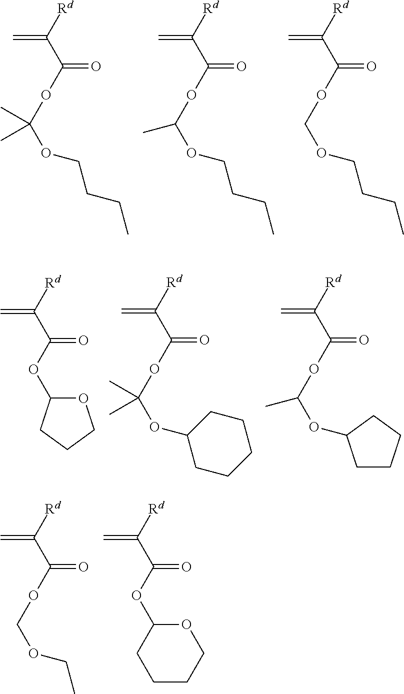

wherein R^{d} is as defined above for R^{a}.

Non-limiting examples of monomers (2d) include:

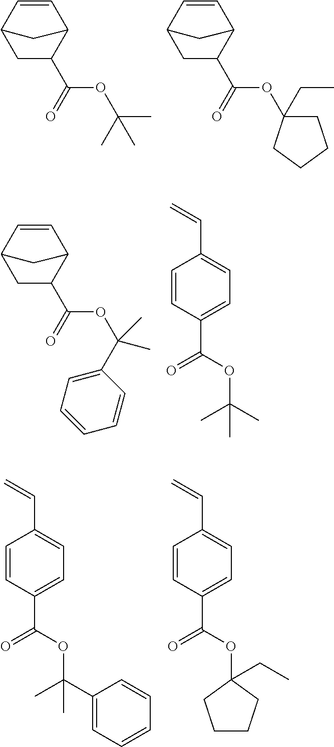

Non-limiting examples of monomers (2e) include:

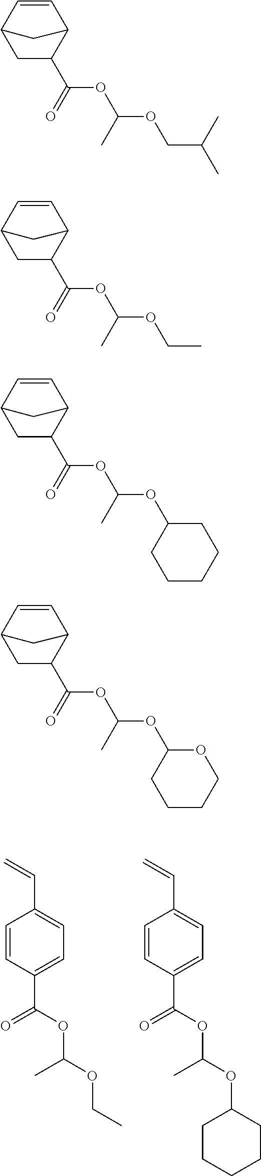 [SMILES: CC(C)COC(C)OC(=O)C1CC2C=CC1C2 ; CCOC(C)OC(=O)C1CC2C=CC1C2 ; CC(OC(=O)C1CC2C=CC1C2)OC1CCCCC1 ; CC(OC(=O)C1CC2C=CC1C2)OC1CCCCO1 ; C=Cc1ccc(C(=O)OC(C)OCC)cc1 ; C=Cc1ccc(C(=O)OC(C)OC2CCCCC2)cc1]

In still another example, the repeating unit having an acid-labile group of the first polymer may be derived from one or more monomers having a cyclic acetal or cyclic ketal group, for example, of the formulas:

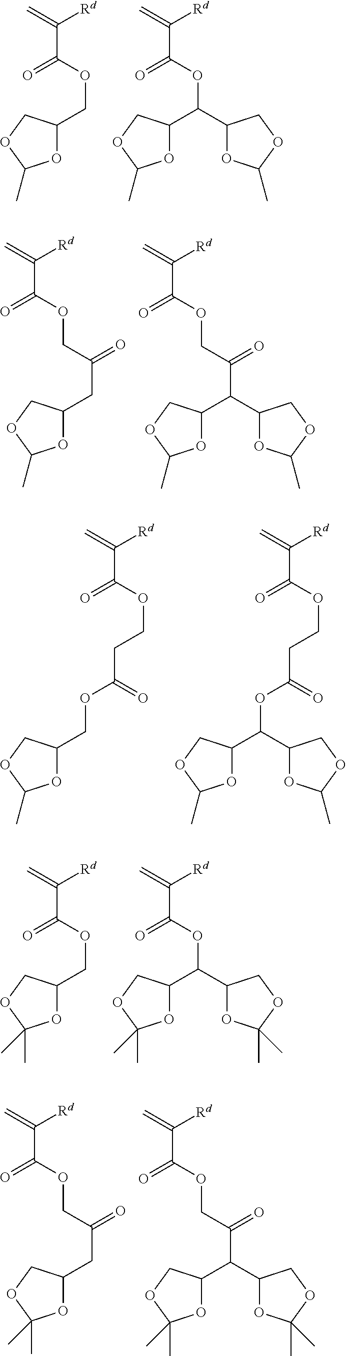

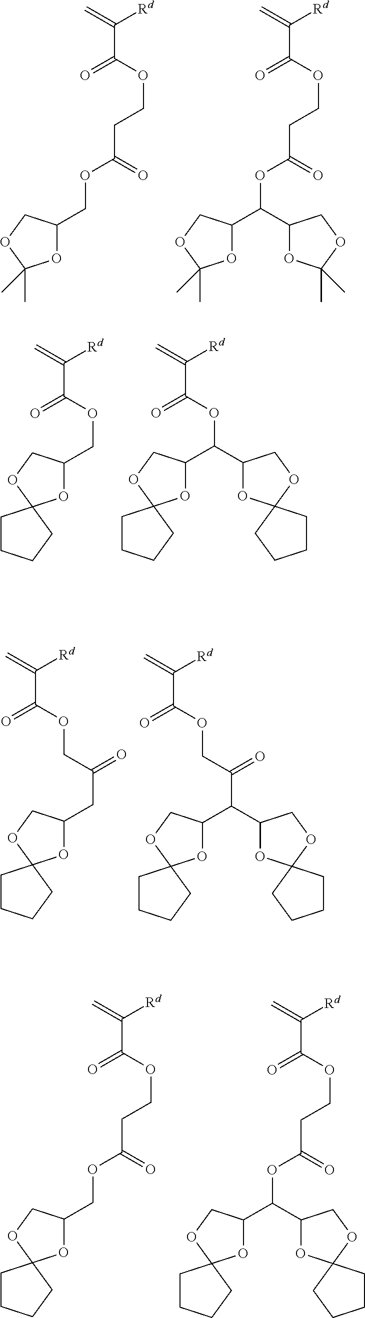

wherein R^{d} is as defined above for R^{a}.

In still another example, the repeating unit having the acid-labile group of the first polymer may be derived from one or more monomers having a tertiary alkoxy group, for example, of the formulas:

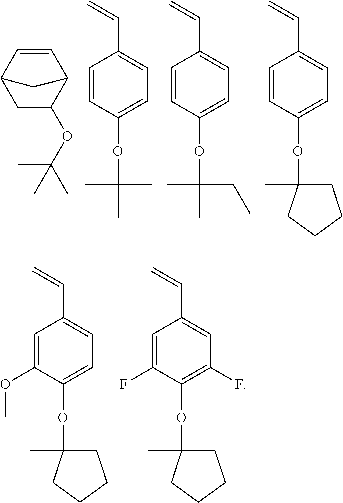

The polymer typically has a weight average molecular weight (M_{w}) from 1,000 to 50,000 Daltons (Da), preferably from 2,000 to 30,000 Da, more preferably from 3,000 to 20,000 Da, and still more preferably from 3,000 to 10,000 Da. The polydispersity index (PDI) of the polymer, which is the ratio of M_{w} to number average molecular weight (Mₙ) is typically from 1.1 to 3, and more typically from 1.1 to 2. Molecular weight values are determined by gel permeation chromatography (GPC) using polystyrene standards.

The polymer may be prepared using any suitable methods in the art. For example, one or more monomers corresponding to the repeating units described herein may be combined, or fed separately, using suitable solvent(s) and initiator, and polymerized in a reactor. For example, the polymers may be obtained by polymerization of the respective monomers under any suitable conditions, such as by heating at an effective temperature, irradiation with actinic radiation at an effective wavelength, or a combination thereof.

In some aspects, the inventive polymer may be a matrix polymer. In other aspects, the inventive polymer may be a surface active polymer.

Optional additional polymers can be present in the topcoat compositions. For example, an optional additional polymer can be provided in addition to the matrix polymer and surface active polymer for purposes of tuning the resist feature profile and/or for controlling resist top loss. Additional polymers are typically miscible with the matrix polymer and substantially immiscible with the surface active polymer such that the surface active polymer can self-segregate from the other polymers to the topcoat surface away from the topcoat/photoresist interface.

Typical solvent materials to formulate and cast a topcoat composition are any which dissolve or disperse the components of the topcoat composition but do not appreciably dissolve an underlying photoresist layer if the topcoat composition is applied to the photoresist layer. Preferably the total solvent is organic-based (i.e., greater than 50 wt % organic), typically from 90 to 100 wt %, more typically from 99 to 100 wt %, or 100 wt % organic solvent, not inclusive of residual water or other contaminants which may, for example, be present in an amount from 0.05 to 1 wt %, based on the total solvent. Preferably, a mixture of different solvents, for example, two, three or more solvents, can be used to achieve effective phase separation of the segregating, surface active polymer from other polymer(s) in the composition. A solvent mixture can also be effective to reduce the viscosity of the formulation which allows for reduction in the dispense volume.

In an exemplary aspect, a two-solvent system or a three-solvent system can be used in the topcoat compositions of the invention. A preferred solvent system includes a primary solvent and an additive solvent and may include a thinner solvent. The primary solvent typically exhibits excellent solubility characteristics with respect to the non-solvent components of the topcoat composition. While the desired boiling point of the primary solvent will depend on the other components of the solvent system, the boiling point is typically less than that of the additive solvent, with a boiling point of from 100 to 200° C. such as about 130° C. being typical.

Suitable primary solvents include, for example, C₄₋₁₀ monovalent alcohols, such as n-butanol, iso-butanol, 2-methyl-1-butanol, iso-pentanol, 2,3-dimethyl-1-butanol, 4-methyl-2-pentanol, iso-hexanol, iso-heptanol, 1-octanol, 1-nonanol and 1-decanol, and mixtures thereof. The primary solvent is typically present in an amount of from 30 to 80 wt % based on the solvent system.

The additive solvent can facilitate phase separation between polymer(s) in the topcoat composition. In addition, the higher boiling point additive solvent can reduce the tip drying effect during coating. It is typical for the additive solvent to have a higher boiling point than the other components of the solvent system. While the desired boiling point of the additive solvent will depend on the other components of the solvent system, a boiling point of from 170 to 250° C. such as about 190° C. is typical. Suitable additive solvents include, for example, hydroxy alkyl ethers such as those of the following general formula (V):

R²⁴—O—R²⁵—O—R²⁶—OH (V)

wherein R²⁴ is an optionally substituted C₁₋₂ alkyl group and R²⁵ and R²⁶ are each independently chosen from optionally substituted C₂₋₄ alkyl groups, and mixtures of such hydroxy alkyl ethers including isomeric mixtures. Exemplary hydroxy alkyl ethers include dialkylene glycol mono-alkyl ethers and isomers thereof, for example, diethylene glycol monomethyl ether, dipropylene glycol monomethyl ether, tripropylene glycol monomethyl ether, isomers thereof and mixtures thereof. The additive solvent is typically present in an amount of from 3 to 15 wt % based on the solvent system.

A thinner solvent can be used to lower the viscosity and improve coating coverage at a lower dispensing volume. The thinner solvent is typically a poorer solvent for the non-solvent components of the composition relative to the primary solvent. While the desired boiling point of the thinner solvent will depend on the other components of the solvent system, a boiling point of from 100 to 200° C. such as about 170° C. is typical. Suitable thinner solvents include, for example, alkanes such as C₈₋₁₂ n-alkanes, for example, n-octane, n-decane and dodecane, isomers thereof and mixtures of isomers thereof; and/or alkyl ethers such as those of the formula R²⁷—O—R²⁸, wherein R²⁷ and R²⁸ are each independently chosen from C₂₋₈ alkyl, C₂₋₆ alkyl, and C₂₋₄ alkyl. The alkyl ether groups can be linear or branched, and symmetric or asymmetric. Particularly suitable alkyl ethers include, for example, isobutyl ether, isopentyl ether, isobutyl isohexyl ether, and mixtures thereof. Other suitable thinner solvents include ester solvents, for example, those represented by general formula (VI):

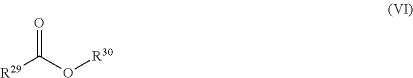

wherein: R²⁹ and R³⁰ are each independently chosen from C₃₋₈ alkyl; and the total number of carbon atoms in R²⁹ and R³⁰ taken together is greater than 6. Suitable such ester solvents include, for example, propyl pentanoate, isopropyl pentanoate, isopropyl 3-methylbutanoate, isopropyl 2-methylbutanoate, isopropyl pivalate, isobutyl isobutyrate, 2-methylbutyl isobutyrate, 2-methylbutyl-2-methylbutanoate, 2-methylbutyl-2-methylhexanoate, 2-methylbutyl heptanoate, hexyl heptanoate, n-butyl n-butyrate, isoamyl n-butyrate and isoamyl isovalerate. The thinner solvent if used is typically present in an amount of from 10 to 70 wt % based on the solvent system.

A particularly preferred solvent system includes 4-methyl-2-pentanol, dipropylene glycol methyl ether and isobutyl isobutyrate. While the exemplary solvent system has been described with respect to two-and three-component systems, it should be clear that additional solvents may be used. For example, one or more additional primary solvents, thinner solvents, additive solvents, and/or other solvents may be employed.

The topcoat compositions may comprise one or more other optional components. For example, the compositions can include one or more of actinic and contrast dyes for enhancing antireflective properties, anti-striation agents, and the like. Such optional additives if used are typically present in the composition in minor amounts such as from 0.1 to 10 wt % based on total solids of the topcoat composition.

It may be beneficial to include an acid generator compound such as a photoacid generator (PAG) and/or a thermal acid generator (TAG) compound in the topcoat compositions. Suitable photoacid generators are known in the art of chemically amplified photoresists and include, for example: onium salts, for example, triphenylsulfonium trifluoromethanesulfonate, (p-tert -butoxyphenyl)diphenylsulfonium trifluoromethanesulfonate, tris(p-tert-butoxyphenyl)sulfonium trifluoromethanesulfonate, triphenylsulfonium p-toluenesulfonate; nitrobenzyl derivatives, for example, 2-nitrobenzyl-p-toluenesulfonate, 2,6-dinitrobenzyl-p-toluenesulfonate, and 2,4-dinitrobenzyl-p -toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n -butanesulfonyl)-α-dimethylglyoxime; sulfonic acid ester derivatives of an N-hydroxyimide compound, for example, N-hydroxysuccinimide methanesulfonic acid ester, N-hydroxy succinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine. One or more of such PAGs can be used.

Suitable thermal acid generators include, for example, nitrobenzyl tosylates, such as 2-nitrobenzyl tosylate, 2,4-dinitrobenzyl tosylate, 2,6-dinitrobenzyl tosylate, 4-nitrobenzyl tosylate; benzenesulfonates such as 2-trifluoromethyl-6-nitrobenzyl 4chlorobenzenesulfonate, 2-trifluoromethyl-6-nitrobenzyl 4-nitro benzenesulfonate; phenolic sulfonate esters such as phenyl, 4-methoxybenzenesulfonate; alkyl ammonium salts of organic acids, such as triethylammonium salt of 10-camphorsulfonic acid, trifluoromethylbenzenesulfonic acid, perfluorobutane sulfonic acid; and particular onium salts. A variety of aromatic (anthracene, naphthalene, or benzene derivatives) sulfonic acid amine salts can be employed as the TAG, including those disclosed in U.S. Pat. Nos. 3,474,054, 4,200,729, 4,251,665 and 5,187,019. Examples of TAGs include those sold by King Industries, Norwalk, Conn. USA under NACURE™, CDX™ and K-PURE™ names, for example, NACURE 5225, CDX-2168E, K-PURE™ 2678 and KPURE™ 2700. One or more of such TAGs can be used.

If employed, the one or more acid generators may be utilized in relatively lesser amounts in a topcoat composition, for example, from 0.1 to 8 wt %, based on total solids of the composition. Such use of one or more acid generator compounds may favorably impact lithographic performance, particularly resolution, of the developed image patterned in an underlying resist layer.

Topcoat layers formed from the compositions typically have an index of refraction of 1.4 or greater at 193 nm, preferably 1.47 or greater at 193 nm. The index of refraction can be tuned by changing the composition of the matrix polymer, the surface active polymer, the additive polymer, or other components of the overcoat composition. For example, increasing the relative amount of organic content in the overcoat composition may provide increased refractive index of the layer. Preferred overcoat composition layers will have a refractive index between that of the immersion fluid and the photoresist at the target exposure wavelength.

The photoresist topcoat compositions can be prepared following known procedures. For example, the compositions can be prepared by dissolving solid components of the composition in the solvent components. The desired total solids content of the compositions will depend on factors such as the particular polymers in the composition and desired final layer thickness. Preferably, the solids content of the overcoat compositions is from 1 to 10 wt %, more preferably from 1 to 5 wt %, based on the total weight of the composition. The viscosity of the entire composition is typically from 1.5 to 2 centipoise (cP).

Photoresist compositions useful in the methods of the invention include chemically-amplified photoresist compositions comprising a matrix polymer that is acid-sensitive, meaning that as part of a layer of the photoresist composition, the polymer and composition layer undergo a change in solubility in a developer as a result of reaction with acid generated by a photoacid generator following softbake, exposure to activating radiation and post exposure bake. The resist formulation can be positive-acting or negative-acting, but is typically positive-acting. In positive-type photoresists, the change in solubility is typically brought about when acid-labile groups such as photoacid-labile ester or acetal groups in the matrix polymer undergo a photoacid-promoted deprotection reaction on exposure to activating radiation and heat treatment. Suitable photoresist compositions useful for the invention are commercially available.

For imaging at wavelengths such as 193 nm, the matrix polymer is typically substantially free (e.g., less than 15 mole %) or completely free of phenyl, benzyl, or other aromatic groups where such groups are highly absorbing of the radiation. Suitable polymers that are substantially or completely free of aromatic groups are disclosed in European application EP930542A1 and U.S. Pat. Nos. 6,692,888 and 6,680,159, all of the Shipley Company. Preferable acid-labile groups include, for example, acetal groups or ester groups that contain a tertiary non-cyclic alkyl carbon (e.g., t-butyl) or a tertiary alicyclic carbon (e.g., methyladamantyl) covalently linked to a carboxyl oxygen of an ester of the matrix polymer.

Suitable matrix polymers further include polymers that contain (alkyl)acrylate units, preferably including acid-labile (alkyl)acrylate units, such as t-butyl acrylate, t-butyl methacrylate, methyladamantyl acrylate, methyladamantyl methacrylate, ethylfenchyl acrylate, ethylfenchyl methacrylate, and the like, and other non-cyclic alkyl and alicyclic (alkyl)acrylates. Such polymers have been described, for example, in U.S. Pat. No. 6,057,083, European Published Applications EP01008913A1 and EP00930542A1, and U.S. Pat. No. 6,136,501. Other suitable matrix polymers include, for example, those which contain polymerized units of a non-aromatic cyclic olefin (endocyclic double bond) such as an optionally substituted norbornene, for example, polymers described in U.S. Pat. Nos. 5,843,624 and 6,048,664. Still other suitable matrix polymers include polymers that contain polymerized anhydride units, particularly polymerized maleic anhydride and/or itaconic anhydride units, such as disclosed in European Published Application EP01008913A1 and U.S. Pat. No. 6,048,662.

Also suitable as the matrix polymer is a resin that contains repeat units that contain a heteroatom, particularly oxygen and/or sulfur (but other than an anhydride, i.e., the unit does not contain a keto ring atom). The heteroalicyclic unit can be fused to the polymer backbone and can comprise a fused carbon alicyclic unit such as provided by polymerization of a norbornene group and/or an anhydride unit such as provided by polymerization of a maleic anhydride or itaconic anhydride. Such polymers are disclosed in PCT/US01/14914 and U.S. Pat. No. 6,306,554. Other suitable heteroatom group-containing matrix polymers include polymers that contain polymerized carbocyclic aryl units substituted with one or more heteroatom (e.g., oxygen or sulfur) containing groups, for example, hydroxy naphthyl groups, such as disclosed in U.S. Pat. No. 7,244,542.

Blends of two or more of the above-described matrix polymers can suitably be used in the photoresist compositions.

Suitable matrix polymers for use in the photoresist compositions are commercially available and can be readily made by persons skilled in the art. The matrix polymer is present in the resist composition in an amount sufficient to render an exposed coating layer of the resist developable in a suitable developer solution. Typically, the matrix polymer is present in the composition in an amount of from 50 to 95 wt % based on total solids of the resist composition. The weight average molecular weight M_{w} of the matrix polymer is typically less than 100,000 Da, for example, from 5000 to 100,000 Da, more typically from 5000 to 15,000 Da.

The photoresist composition further comprises a photoactive component such as a photoacid generator (PAG) employed in an amount sufficient to generate a latent image in a coating layer of the composition upon exposure to activating radiation. For example, the photoacid generator will suitably be present in an amount from about 1 to 20 wt % based on total solids of the photoresist composition. Typically, lesser amounts of the PAG will be suitable for chemically amplified resists as compared with non-chemically amplified materials. Suitable PAGs are known in the art of chemically amplified photoresists and include, for example, those described above with respect to the topcoat composition.

Suitable solvents for the photoresist compositions include, for example: glycol ethers such as 2-methoxyethyl ether (diglyme), ethylene glycol monomethyl ether, and propylene glycol monomethyl ether; propylene glycol monomethyl ether acetate; lactates such as methyl lactate and ethyl lactate; propionates such as methyl propionate, ethyl propionate, ethyl ethoxy propionate and methyl-2-hydroxy isobutyrate; Cellosolve esters such as methyl Cellosolve acetate; aromatic hydrocarbons such as toluene and xylene; and ketones such as acetone, methylethyl ketone, cyclohexanone and 2-heptanone. A blend of solvents such as a blend of two, three or more of the solvents described above also are suitable. The solvent is typically present in the composition in an amount of from 90 to 99 wt %, more typically from 95 to 98 wt %, based on the total weight of the photoresist composition.

The photoresist compositions can also include other optional materials. For example, the compositions can include one or more of actinic and contrast dyes, anti-striation agents, plasticizers, speed enhancers, sensitizers, and the like. Such optional additives if used are typically present in the composition in minor amounts such as from 0.1 to 10 wt % based on total solids of the photoresist composition.

A preferred optional additive of the resist compositions is an added base. Suitable bases are known in the art and include, for example, linear and cyclic amides and derivatives thereof such as N,N-bis(2-hydroxyethyl)pivalamide, N,N-Diethylacetamide, N1,N1,N3,N3-tetrabutylmalonamide, 1-methylazepan-2-one, 1-allylazepan-2-one and tert-butyl 1,3-dihydroxy-2-(hydroxymethyl)propan-2ylcarbamate; aromatic amines such as pyridine, and di-tert-butyl pyridine; aliphatic amines such as triisopropanolamine, n-tert-butyldiethanolamine, tris(2-acetoxy-ethyl) amine, 2,2′,2″,2″″-(ethane-1,2-diylbis(azanetriyl)tetraethanol, and 2-(dibutylamino)ethanol, 2,2′,2″-nitrilotriethanol; cyclic aliphatic amines such as 1-(tert-butoxycarbonyl)-4-hydroxypiperidine, tert-butyl 1-pyrrolidinecarboxylate, tert-butyl 2-ethyl-1H-imidazole-1-carboxylate, di-tert-butyl piperazine-1,4-dicarboxylate and N (2-acetoxy -ethyl) morpholine. The added base is suitably used in lesser amounts, for example, from 0.01 to 5 wt %, preferably from 0.1 to 2 wt %, based on total solids of the photoresist composition.

Additionally, or alternatively, the resist compositions may further include one or more additive polymers in addition to and different from the polymers described above. For example, the resist composition may include an additional polymer as described above but different in composition. Additionally, or alternatively, the one or more additional polymers may include those well known in the photoresist art, for example, those chosen from polyacrylates, polyvinylethers, polyesters, polynorbornenes, polyacetals, polyethylene glycols, polyamides, polyacrylamides, polyphenols, novolacs, styrenic polymers, polyvinyl alcohols, or combinations thereof.

The resist compositions may further include one or more additional, optional additives. For example, optional additives may include actinic and contrast dyes, anti-striation agents, plasticizers, speed enhancers, sensitizers, photo-decomposable quenchers (PDQ) (and, also known as photo-decomposable bases), basic quenchers, thermal acid generators, surfactants, and the like, or combinations thereof. If present, the optional additives are typically present in the resist compositions in an amount of from 0.01 to 10 wt %, based on total solids of the resist composition.

The photoresists can be prepared following known procedures. For example, the resists can be prepared as coating compositions by dissolving the solid components of the photoresist in the solvent component. The desired total solids content of the photoresist will depend on factors such as the particular polymers in the composition, final layer thickness and exposure wavelength. Typically, the solids content of the photoresist varies from 1 to 10 wt %, more typically from 2 to 5 wt %, based on the total weight of the photoresist composition.

Photoresist compositions used in the methods of the invention are suitably applied to a substrate in a conventional manner for applying photoresists. Liquid photoresist compositions can be applied to a substrate such as by spin-coating, dipping, roller-coating or other conventional coating technique, with spin-coating being typical. When spin coating, the solids content of the coating solution can be adjusted to provide a desired film thickness based upon the specific spinning equipment utilized, the viscosity of the solution, the speed of the spinner and the amount of time allowed for spinning For example, applying the layer of photoresist and/or topcoat may be accomplished by spin coating the photoresist in solvent using a coating track, in which the photoresist is dispensed on a spinning wafer. During dispensing, the wafer is typically spun at a speed of up to 4,000 rotations per minute (rpm), for example, from 200 to 3,000 rpm, for example, 1,000 to 2,500 rpm, for a period from 15 to 120 seconds to obtain a layer of the photoresist on the substrate. It will be appreciated by those skilled in the art that the thickness of the coated layer may be adjusted by changing the spin speed and/or the solids content of the composition. A photoresist layer typically has a dried layer thickness from 10 to 500 nanometers (nm), preferably from 15 to 200 nm, and more preferably from 20 to 120 nm.

Suitable substrates on which the photoresist compositions can be coated include electronic device substrates. A wide variety of electronic device substrates may be used in the present invention, such as: semiconductor wafers; polycrystalline silicon substrates; packaging substrates such as multichip modules; flat panel display substrates; substrates for light emitting diodes (LEDs) including organic light emitting diodes (OLEDs); and the like, with semiconductor wafers being typical. Such substrates are typically composed of one or more of silicon, polysilicon, silicon oxide, silicon nitride, silicon oxynitride, silicon germanium, gallium arsenide, aluminum, sapphire, tungsten, titanium, titanium-tungsten, nickel, copper, and gold. Suitable substrates may be in the form of wafers such as those used in the manufacture of integrated circuits, optical sensors, flat panel displays, integrated optical circuits, and LEDs. Such substrates may be any suitable size. Typical wafer substrate diameters are 200 to 300 millimeters (mm), although wafers having smaller and larger diameters may be suitably employed according to the present invention. The substrates may include one or more layers or structures which may optionally include active or operable portions of devices being formed. The photoresist compositions are typically applied over an antireflective layer, for example, an organic antireflective layer.

Typically, one or more lithographic layers such as a hardmask layer, for example, a spin-on-carbon (SOC), amorphous carbon, or metal hardmask layer, a CVD layer such as a silicon nitride (SiN), a silicon oxide (SiO), or silicon oxynitride (SiON) layer, an organic or inorganic underlayer, or combinations thereof, are provided on an upper surface of the substrate prior to coating a photoresist composition . Such layers, together with an overcoated photoresist layer, form a lithographic material stack.

Optionally, a layer of an adhesion promoter may be applied to the substrate surface prior to coating the photoresist topcoat compositions. If an adhesion promoter is desired, any suitable adhesion promoter for polymer films may be used, such as silanes, typically organosilanes such as trimethoxyvinylsilane, triethoxyvinylsilane, hexamethyldisilazane, or an aminosilane coupler such as gamma-aminopropyltriethoxysilane. Particularly suitable adhesion promoters include those sold under the AP 3000, AP 8000, and AP 9000S designations, available from DuPont Electronics & Imaging (Marlborough, Mass.).

A topcoat composition of the invention can be applied over the photoresist composition by any suitable method such as described above with reference to the photoresist compositions, with spin-coating being typical.

Following coating of the photoresist onto a surface, it may be heated (softbaked) to remove the solvent until typically the photoresist coating is tack free, or the photoresist layer may be dried after the topcoat composition has been applied and the solvent from both the photoresist composition and topcoat composition layers substantially removed in a single thermal treatment step. The soft bake is performed, for example, on a hotplate or in an oven, with a hotplate being typical. The soft bake temperature and time will depend, for example, on the particular photoresist composition and thickness. The soft bake temperature is typically from 90 to 170° C., and more typically from 90 to 150° C. The soft bake time is typically from 10 seconds to 20 minutes, more typically from 1 minute to 10 minutes, and still more typically from 1 minute to 5 minutes. The heating time can be readily determined by one of ordinary skill in the art based on the ingredients of the composition.

The photoresist layer with overcoated topcoat layer is next pattern-wise exposed to activating radiation to create a difference in solubility between exposed and unexposed regions. Reference herein to exposing a photoresist topcoat composition to radiation that is activating for the composition indicates that the radiation is capable of forming a latent image in the photoresist composition. The exposure is typically conducted through a patterned photomask that has optically transparent and optically opaque regions corresponding to regions of the resist layer to be exposed and unexposed, respectively. Such exposure may, alternatively, be conducted without a photomask in a direct writing method, typically used for e-beam lithography. The activating radiation typically has a wavelength of sub-400 nm, sub-300 nm or sub-200 nm, with 248 nm (KrF), 13.5 nm (EUV) wavelengths or e-beam lithography being preferred. The methods find use in immersion or dry (non-immersion) lithography techniques. The exposure energy is typically from 1 to 200 millijoules per square centimeter (mJ/cm²), preferably from 10 to 100 mJ/cm² and more preferably from 20 to 50 mJ/cm², dependent upon the exposure tool and components of the photoresist topcoat composition. The exposure is typically conducted with an immersion scanner but can alternatively be conducted with a dry (non-immersion) exposure tool.

Following exposure and photoactivation of the photoresist layer (and topcoat composition if photosensitive), a post-exposure bake (PEB) of the exposed photoresist layer is performed. The PEB can be conducted, for example, on a hotplate or in an oven, with a hotplate being typical. Conditions for the PEB will depend, for example, on the particular photoresist topcoat composition and layer thickness. The PEB is typically conducted at a temperature from 80 to 150° C., and a time from 30 to 120 seconds. A latent image defined by the polarity-switched (exposed regions) and unswitched regions (unexposed regions) is formed in the photoresist.

Thereafter, the film is developed. In general, development is in accordance with procedures recognized in the art. In the case of a positive-tone development (PTD) process, the exposed regions of the photoresist layer and topcoat layer are removed during development and unexposed regions remain. Conversely, in a negative-tone development (NTD) process, the exposed regions of the photoresist layer remain, and unexposed regions and topcoat layer are removed during development. Application of the developer may be accomplished by any suitable method such as described above with respect to application of the photoresist topcoat composition, with spin coating being typical. The development time is for a period effective to remove the soluble regions of the photoresist, with a time of from 5 to 60 seconds being typical. Development is typically conducted at room temperature.

Suitable developers for a PTD process include aqueous base developers, for example, quaternary ammonium hydroxide solutions such as tetramethylammonium hydroxide (TMAH), preferably 0.26 normal (N) TMAH, tetraethylammonium hydroxide, tetrabutylammonium hydroxide, amine solutions such as ethyl amine, n-propyl amine, diethyl amine, di-n-propyl amine, triethyl amine, or methyldiethyl amine; alcohol amines such as diethanol amine or triethanol amine; and cyclic amines such as pyrrole or pyridine; sodium hydroxide, potassium hydroxide, sodium carbonate, potassium carbonate, and the like. Suitable developers for an NTD process are organic solvent-based, meaning the cumulative content of organic solvents in the developer is 50 wt % or more, typically 95 wt % or more, 98 wt % or more, or 100 wt %, based on total weight of the developer. Suitable organic solvents for the NTD developer include, for example, those chosen from ketones, esters, ethers, hydrocarbons, and mixtures thereof. The developer is typically 2-heptanone or n-butyl acetate.

Following development of the photoresist layer, the developed substrate may be selectively processed on those areas bared of resist, for example by chemically etching or plating substrate areas bared of resist in accordance with procedures known in the art. After such processing, the resist remaining on the substrate can be removed from the using known stripping procedures.

A coated substrate may be formed from the topcoat compositions of the invention. Such a coated substrate includes: (a) a photoresist layer on a substrate; and (b) a topcoat layer formed on the photoresist layer, wherein the topcoat layer is derived from the topcoat composition.

The photoresist pattern may be used, for example, as an etch mask, thereby allowing the pattern to be transferred to one or more sequentially underlying layers by known etching techniques, typically by dry-etching such as reactive ion etching. The photoresist pattern may, for example, be used for pattern transfer to an underlying hardmask layer which, in turn, is used as an etch mask for pattern transfer to one or more layers below the hardmask layer. If the photoresist pattern is not consumed during pattern transfer, it may be removed from the substrate by known techniques, for example, oxygen plasma ashing. The photoresist topcoat compositions may, when used in one or more such patterning processes, be used to fabricate semiconductor devices such as memory devices, processor chips (CPUs), graphics chips, optoelectronic chips, LEDs, OLEDs, as well as other electronic devices.

The invention is further illustrated by the following examples.

### EXAMPLES

Synthesis of Monomer 1: Methacrylamide (10.0 g, 1.0 equivalent) and dimethylaminopyridine (1.45 g, 0.1 equivalent) are dissolved in 250 mL of dichloromethane. Di-tert-butyl decarbonate (53.9 g, 2.1 equivalents) is added slowly and the reaction is left stirring at room temperature for 16 hours. The reaction mixture is then washed with saturated sodium bicarbonate, water, and brine, and then dried over magnesium sulfate. The solvent is removed under reduced pressure to give Monomer 1.

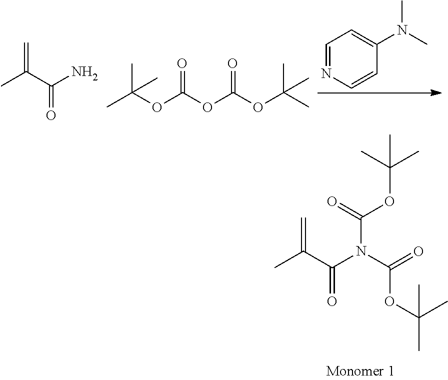

Synthesis of Monomer 2: N-hydroxy-5-norbornane-2,3-dicarboxylic acid imide (15.8 g, 1.0 equivalent) and triethylamine (13.2 g, 1.5 equivalent) are dissolved in 200 mL dichloromethane. The reaction mixture is cooled to 0° C. and methacryloyl chloride (10.0 g, 1.1 equivalent) is slowly added thereto. The reaction mixture continues stirring at 23-25° C. for 16 hours. The reaction mixture is then washed with saturated sodium bicarbonate, water, and brine, and is then dried over magnesium sulfate. The solvent is removed under reduced pressure to give Monomer 2.

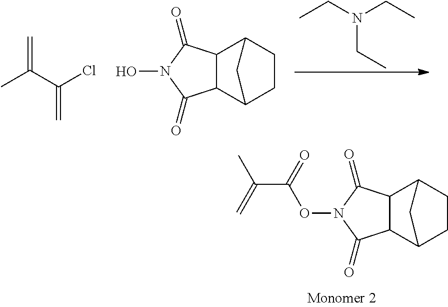

Synthesis of Monomer 13A, 13B, 13C, and 13D: Monomer 13A was prepared as shown Scheme 1:

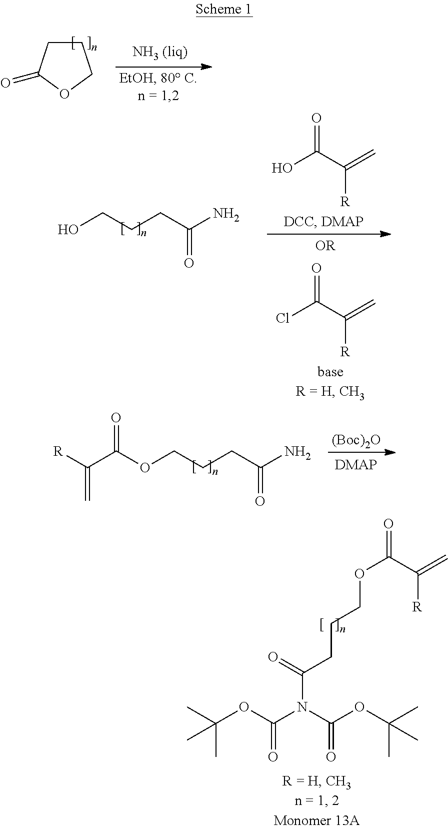

wherein R=CH₃, n=2 (Boc)₂O is di-tert-butyl dicarbonate and DMAP is 4-dimethylaminopyridine.

Similarly, Monomer 13B (R=CH₃, n=1), Monomer 13C (R=H, n=2), and Monomer 13D (R =H, n=1) are prepared as shown in Scheme 1, where (Boc)₂O and DMAP are as defined above.

Synthesis of 5-Hydroxypentanamide: A 2-L autoclave was charged with tetrahydro-2H-pyran -2-one (80.0 g, 799.04 mmol) in ethanol (200 mL, 2.5 vol), the of the contents of the autoclave were cooled below -30° C., and liquid ammonia (400 mL, 5 vol) was added thereto. The autoclave was sealed, and the reaction mixture was heated to 90-100° C. at 500-575 psi for 24 h. Then, the reaction mixture cooled to room temperature and a resulting solid was filtered from the mixture. The wet cake of the resulting solid was washed with ethyl acetate (300 mL, 3.75 vol) and dried under vacuum to give 5-hydroxypentanamide (64.0 g, 68%) as a white solid. ¹H NMR δ(ppm): 7.20 (bs, 1H), 6.67 (bs, 1H), 4.36 (t, J=8.0 Hz, 1H); 3.39 (t, J=12 Hz, 2H), 1.53-1.47 (m, 2H), and 1.46-1.39 (m, 2H); FT-IR: 3400.56 cm⁻¹ (—OH, strong), 1643.3 cm⁻¹ (—C═O, amide), and 3183.57 cm⁻¹ (—N—H, amide); UPLC-ELSD: 99.84% purity (at 1.49 RT); MS: m/z=118.13[M+H]⁺.

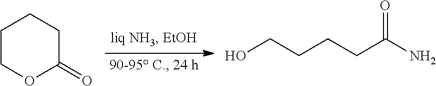 [SMILES: O=C1CCCCO1 ; NC(=O)CCCCO]

Synthesis of 5-Amino-5-oxopentyl methacrylate: A 250 mL 3-neck round bottom flask equipped with magnetic stir bar, internal thermometer, and nitrogen bubbler was charged with 5-hydroxypentanamide (5.0 g, 42.68 mmol) in dry dichloromethane (100 mL) at room temperature. N,N-dimethyl-4-aminopyridine (521 mg, 4.27 mmol) and triethylamine (11.9 mL, 85.36 mmol) were added thereto and the resulting suspension was stirred for 15 minutes. Methylacryloylchloride (5 mL, 51.21 mmol) was then added drop wise and the resulting mixture was stirred at room temperature for 16 h. The reaction product mixture was diluted with dichloromethane (100 mL) and washed with chilled water (100 mL) and a brine solution (50 mL). The organic layer was separated and dried over anhydrous sodium sulfate, filtered, and concentrated under reduced pressure. The crude material was triturated with 10% dichloromethane in hexanes to give 5-amino-5-oxopentyl methacrylate (6.0 g, 75%) as a pale-yellow solid. ¹H NMR δ(ppm): 7.25 (bs, 1H), 6.71 (bs, 1H), 6.02-6.01 (m, 1H), 5.67-5.66 (m, 1H); 4.13-4.07 (m, 2H), 1.88 (s, 3H), 1.64-1.57 (m, 4H); FT-IR: 2955.0 cm⁻¹ (—C=C—H stretch) 1649.17 cm⁻¹ (—C═O, amide), 1717.64 cm⁻¹ (—C═O, ester) and 3193.21 cm⁻¹ (—N—H, amide), LCMS-ELSD: 92.7% purity (at 1.40 RT); MS: m/z=186.23 [M+H]⁺.

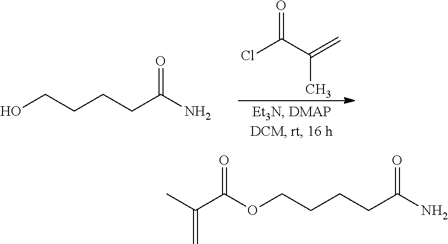

Synthesis of [5-[Bis(tert-butoxycarbonyl)amino]-5-oxo-pentyl]2-methylprop-2-enoate (Monomer 13A): A 25 mL 3-neck round bottom flask equipped with magnetic stir bar and nitrogen bubbler was charged with 5-amino-5-oxopentyl methacrylate (200 mg, 1.08 mmol), N,N-dimethyl-4-aminopyridine (26.5 mg, 0.21 mmol), and acetonitrile (4 mL) at room temperature. (Boc)₂O (0.99 mL, 4.32 mmol) was added thereto and the resulting mixture was stirred at room temperature for 16 h, diluted with ethyl acetate (4 mL), and washed with water (2 mL) and brine (2 mL). The organic layer was separated and dried over anhydrous sodium sulfate, filtered, and concentrated under reduced pressure. The crude material was purified by flash column chromatography over silica gel (100-200 mesh) using an elution gradient of 0-3 vol % of ethyl acetate in hexanes to give [5-[bis(tert-butoxycarbonyl)amino]-5-oxo-pentyl]2-methylprop-2-enoate (13, 50 mg, 12%) as a pale yellow liquid. ¹H NMR 8(ppm): 6.02 (t, J=1.6 Hz, 1H), 5.67 (t, J=3.2 Hz, 1H), 4.11 (t, J=12 Hz, 2H), 2.82 (t, J=14 Hz, 2H), 1.88 (s, 3H), 1.66-1.61 (m, 4H), 1.60 (s, 18H); FT-IR: 2982.9 cm⁻¹ (—C=C—H stretch), 1711.8 cm⁻¹ (—C═O, amide), 1787.0 cm⁻¹ (—C—C═O, ester); UPLC-ELSD: 99.55% purity (at 2.85 RT). No ionization was observed in either LCMS or GCMS. The structure of Monomer 13A was confirmed by 2D NMR.

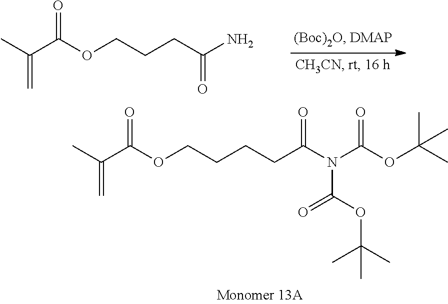 [SMILES: C=C(C)C(=O)OCCCC(N)=O ; C=C(C)C(=O)OCCCCC(=O)N(C(=O)OC(C)(C)C)C(=O)OC(C)(C)C]

Synthesis of Monomer 17: The double-armed Monomer 17 is prepared as shown in Scheme 2:

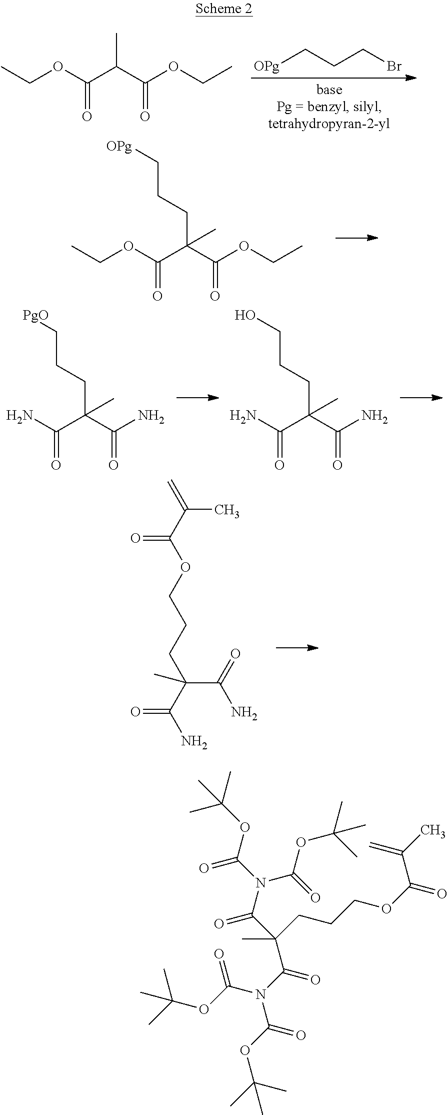

Polymer Synthesis, Protocol 1: Exemplary polymer A2 is prepared as follows. A monomer feed solution is prepared using 23.4 g of propylene glycol monomethyl ether acetate (PGMEA), 10.0 g of Monomer 1, and 1.6 g of Monomer 4. Separately, an initiator feed solution is prepared using 8.3 g of PGMEA and 0.84 g of V-601. In a reactor, 9.4 g of PGMEA is warmed to 80° C., and then the monomer feed solution is added dropwise over 240 minutes, and the initiator feed solution is added dropwise over 90 minutes. After 4 hours, the reaction mixture is cooled to room temperature at 1° C./min, and then the polymer is precipitated by adding directly to 1 L of 9/1 methanol/water (v/v). The polymer is collected by filtration and dried in vacuo to give polymer A2.

Polymer Synthesis, Protocol 2: Exemplary polymer B2 was prepared as follows. A monomer feed solution was prepared by combining 10 g of propylene glycol monomethyl ether (PGME), 7.0 g of Monomer-6, 3.0 g of Monomer-7, and 0.50 g of V-601 initiator in a container, and agitating the mixture to dissolve the components. Next, 8.6 g of PGME was introduced into a reaction vessel and the vessel was purged with nitrogen for 30 minutes. The reaction vessel was then heated at 95° C. with agitation. The feed solution was then introduced into the reaction vessel and fed over 1.5 hours. The reaction vessel was maintained at 95° C. for an additional three hours with agitation and was then allowed to cool to room temperature. The polymer was precipitated by dropwise addition of the reaction mixture into ⅕ methanol/water (v/v), collected by filtration, and dried in vacuo. Polymer B2 was obtained as a white solid powder. M_{w}=12640 Da, PDI=1.8

Each of the polymers in Table 1 is prepared using a synthesis protocol. It is to be noted that the “A” and “CA” polymers in Table 1 are prepared according to synthesis Protocol 1. The “B” polymers are prepared according to general synthesis Protocol 2. The amounts in Table 1 are mole percent (mol %) of repeating units derived from each specified monomer, based on the total moles of repeating units of the polymer.

TABLE 1

| | First | | Second | | Third |
|---|---|---|---|---|---|
| Polymer | Monomer | | Monomer | | Monomer |
| A1 | 1 | (100%) | — | | — |
| A2 | 1 | (80%) | 4 | (20%) | — |
| A3 | 2 | (100%) | | | — |
| A4 | 2 | (80%) | 5 | (20%) | — |
| A5 | 13A | (100%) | — | | — |
| A6 | 13A | (90%) | 4 | (10%) | — |
| B1 | 6 | (60%) | 7 | (30%) | 4 (10%) |
| B2 | 6 | (70%) | 7 | (30%) | — |

The structures of Monomers 1 to 7 and 13 are as follows:

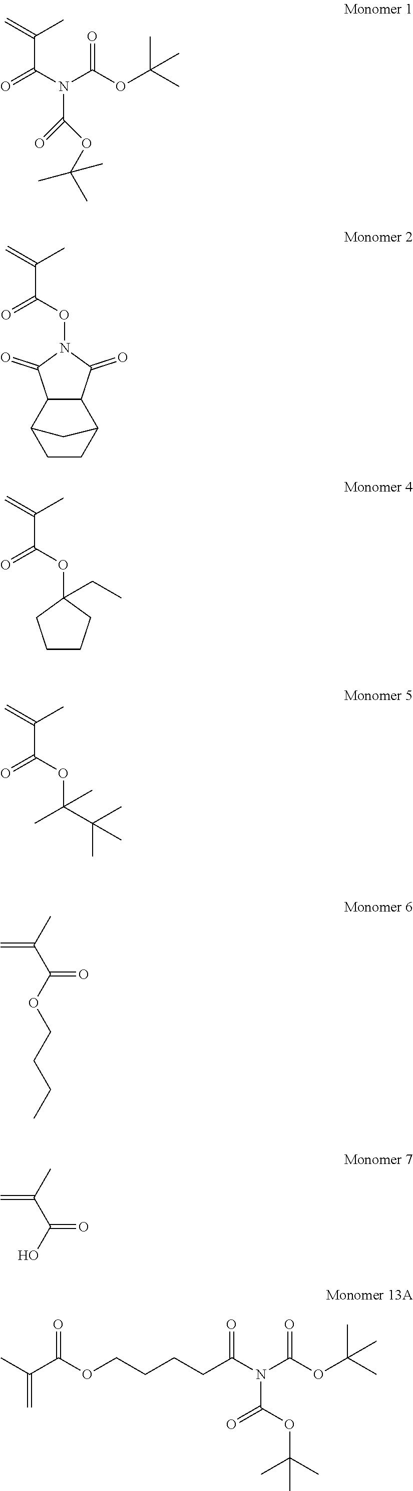

The chemical structures of compounds C1 and D1 are shown below.

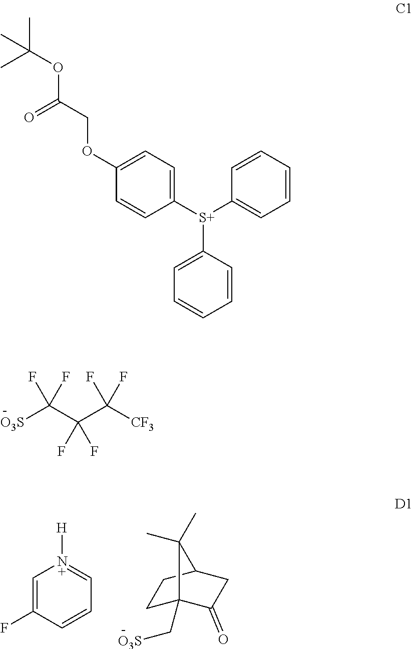

Topcoat Compositions. The formulations T1-T6 (topcoat compositions) are prepared with components and amounts shown in Table 2. In Table 2, the number in bracket indicates the weight ratio of each component, based on 100 wt % of the topcoat composition. Each mixture is filtered through a 0.2 μm PTFE filter prior to coating. The solvents are propylene glycol methyl ether acetate (S1), methyl-2-hydroxyisobutyrate (S2), and dipropylene glycol methyl ether (S3).

TABLE 2

| Topcoat | | | | Solvent | |
|---|---|---|---|---|---|
| Compo- | Polymer | Polymer | Additive | Additive | |
| sition | 1 | 2 | 1 | 2 | System |
| T1 | B2 [1.14] | A1 [0.16] | C1 [0.013] | D1 [0.007] | S1/S2/S3 |
| | | | | | [32.6/60.2/5.9] |
| T2 | B1 [1.14] | A2 [0.16] | C1 [0.013] | D1 [0.007] | S1/S2/S3 |
| | | | | | [32.6/60.2/5.9] |
| T3 | B1 [1.14] | A3 [0.16] | C1 [0.013] | D1 [0.007] | S1/S2/S3 |
| | | | | | [32.6/60.2/5.9] |
| T4 | B2 [1.14] | A4 [0.16] | C1 [0.013] | D1 [0.007] | S1/S2/S3 |
| | | | | | [32.6/60.2/5.9] |
| T5 | B1 [1.14] | A5 [0.16] | C1 [0.013] | D1 [0.007] | S1/S2/S3 |
| | | | | | [32.6/60.2/5.9] |
| T6 | B2 [1.14] | A6 [0.16] | C1 [0.013] | D1 [0.007] | S1/S2/S3 |
| | | | | | [32.6/60.2/5.9] |

Coating Defect Testing. Coating defect testing is performed by coating topcoat compositions with a TEL Lithius wafer track on 300 mm bare silicon wafers. The compositions are coated to a thickness of 385 Å using a dispense time of 2.6 seconds and a softbake at 90° C. for 60 seconds. The coated topcoat layers are inspected on a KLA-Tencor Surfscan SP2 wafer surface inspection tool for detection of particles of 60 nm and larger.

Pattern Defect Testing. 300 mm bare silicon wafers are coated on a TEL Lithius 300 mm wafer track with AR™ 40A bottom antireflective coating (BARC) material (DuPont Electronics & Imaging) and cured at 205° C. for 60 seconds to form an 800 Å first BARC layer. AR™ 104 BARC material (DuPont Electronics & Imaging) is coated over the first BARC layer and cured at 205° C. for 60 seconds to form a 400 Å second BARC layer. EPIC™ 2099 photoresist (DuPont Electronics & Imaging) is coated over the BARC layer stack and softbaked at 95° C. for 60 seconds to form a 950 Å photoresist layer. The topcoat compositions shown in Table 2 are coated over the photoresist layer and softbaked at 90° C. for 60 seconds to form a 385 Å topcoat layer. The wafers are exposed on an ASML 1900i immersion scanner at 1.35 NA, 0.85/0.75 inner/outer sigma, dipole 35Y illumination with X-polarization, through a photomask to form a 45 nm 1:1 line/space pattern. The wafers are post-exposure baked (PEB) at 95° C. for 60 seconds. The wafers are developed with 0.26 N aqueous TMAH developer, rinsed with distilled water, and spun-dry to form photoresist patterns. The patterned wafers are inspected on a KLA-Tencor 2800 defect inspection tool for pattern defects.

The inventive photoresist topcoat compositions T1-T6 are expected to achieve a lower pattern defect density and a reduced coating defect density.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A topcoat composition, comprising:
a polymer comprising a repeating unit derived from one or more monomers of formula (1); and
a solvent, 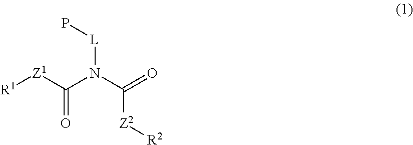
wherein, in formula (1),
Z¹ and Z² are each independently a single bond or a divalent linking group comprising one or more of substituted or unsubstituted C₁₋₃₀ alkylene, substituted or unsubstituted C₁₋₃₀ heteroalkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted C₁₋₃₀ heteroarylene, —O—, —C(O)—, —N(R³)—, —S—, or —S(O)₂—, wherein R³ is hydrogen, substituted or unsubstituted C₁₋₃₀ alkyl, substituted or unsubstituted C₃₋₃₀ cycloalkyl, substituted or unsubstituted C₂₋₃₀ heterocycloalkyl, substituted or unsubstituted C₆₋₃₀ aryl, substituted or unsubstituted C₇₋₃₀ arylalkyl, substituted or unsubstituted C₁₋₃₀ heteroaryl, or substituted or unsubstituted C₂₋₃₀ heteroarylalkyl,
optionally, Z¹ and Z² together form a ring via a single bond or a double bond between Z¹ and Z²,
R¹ and R² are each independently substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, substituted or unsubstituted C₂₋₃₀ alkylheteroaryl, —OR⁴, or —N(R⁵)₂, wherein R⁴ and R⁵ are each independently substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₂₀ heterocycloalkyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl,
optionally, R¹ and R² together form a ring via a single bond or a divalent linking group,
L is a single bond or a multivalent linking group,
optionally, L is a multivalent linking group further comprising an additional group of the formula: 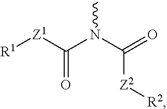
and
P is a polymerizable group.

2. The topcoat composition of claim 1, wherein the polymer comprises a repeating unit derived from one or more monomers of formula (1a): 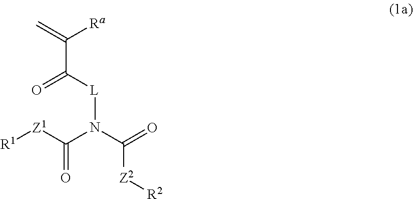
wherein,
R^{a} is hydrogen, fluorine, cyano, a substituted or unsubstituted C₁₋₁₀ alkyl, or a substituted or unsubstituted C₁₋₁₀ fluoroalkyl;
L is a single bond or a multivalent linking group;
optionally, L is a multivalent linking group further comprising an additional group of the formula: 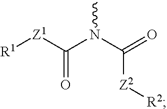
Z¹ and Z² are the same, wherein Z¹ and Z² are chosen from a single bond, —O—, a divalent linking group comprising a group of the formula —C(O)—, or a divalent linking group comprising a group of the formula —C(O)—O—;
R¹ and R² are each independently substituted or unsubstituted C₁₋₃₀ alkyl; and
optionally, R¹ and R² together form a ring via a single bond or a divalent linking group.

3. The topcoat composition of claim 1, wherein,
L is a single bond or a divalent linking group chosen from one or more of substituted or unsubstituted C₁₋₃₀ alkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted divalent C₇₋₃₀ arylalkyl, substituted or unsubstituted C₁₋₃₀ heteroarylene, or substituted or unsubstituted divalent C₂₋₃₀ heteroarylalkyl, —O—, —C(O)—, —C(O)—O—, —C(O)—N(R^{2b})—, —S—, —S(O)₂—, or —N(R^{2b})—S(O)₂— wherein R^{2b} is hydrogen, straight chain or branched C₁₋₂₀ alkyl, monocyclic or polycyclic C₃₋₂₀ cycloalkyl, or monocyclic or polycyclic C₂₋₂₀ heterocycloalkyl.

4. The topcoat composition of claim 1, wherein
L is a group of the formula —C(O)-C₁₋₁₀ alkylene-O-;
Z¹ and Z² are each —O—; and
R¹ and R² are each independently substituted or unsubstituted C₁₋₃₀ alkyl.

5. The topcoat composition of claim 1, further comprising a polymer having a repeating unit that is derived from one or more monomers of formulae (2a), (2b), (2c), (2d), or (2e): 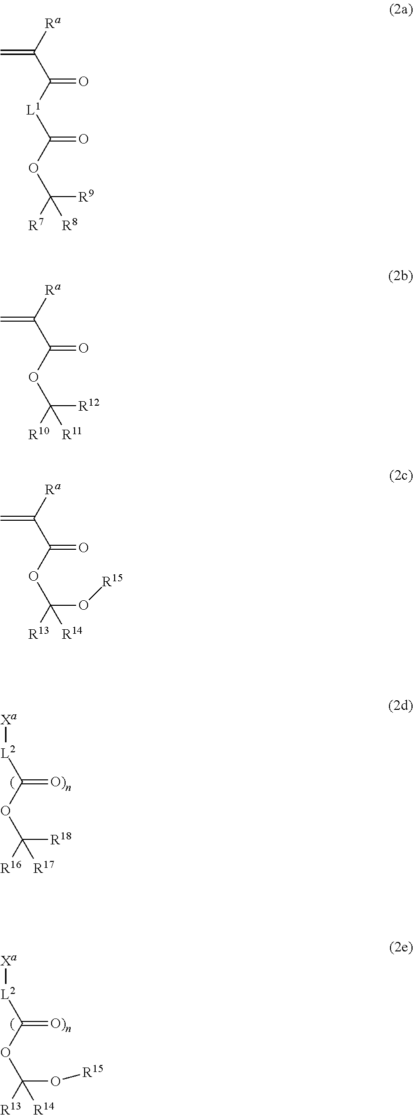
wherein,
is hydrogen, fluorine, cyano, a substituted or unsubstituted C₁₋₁₀ alkyl, or a substituted or unsubstituted C₁₋₁₀ fluoroalkyl;
R⁷ to R¹² are each independently hydrogen, straight chain or branched C₁₋₂₀ alkyl, a monocyclic or polycyclic C₃₋₂₀ cycloalkyl, a monocyclic or polycyclic C₂₋₂₀ heterocycloalkyl, a straight chain or branched C₂₋₂₀ alkenyl, a monocyclic or polycyclic C₃₋₂₀ cycloalkenyl, a monocyclic or polycyclic C₃₋₂₀ heterocycloalkenyl, a monocyclic or polycyclic C₆₋₂₀ aryl, or a monocyclic or polycyclic C₁₋₂₀ heteroaryl, each of which is substituted or unsubstituted;
provided that only one of R⁷ to R⁹ can be hydrogen and only one of R¹⁰ to R¹² can be hydrogen;
any two of R⁷ to R⁹ together optionally form a ring, and each of R⁷ to R⁹ optionally further comprises as part of their structure one or more groups selected from —O—, —C(O)—, —C(O)—O—, —S—, —S(O)₂—, and —N(R¹⁹)—S(O)₂—, wherein R¹⁹ is hydrogen, a straight chain or branched C₁₋₂₀ alkyl, monocyclic or polycyclic C₃₋₂₀ cycloalkyl, or monocyclic or polycyclic C₂₋₂₀ heterocycloalkyl;
any two of R¹° to R¹² together optionally form a ring, and each of R¹⁰ to R¹² optionally further comprises as part of their structure one or more groups selected from —O—, —C(O)—, —C(O)—O—, —S—, —S(O)₂—, and —N(R²⁰)—S(O)₂—, wherein R²⁰ is hydrogen, a straight chain or branched C₁₋₂₀ alkyl, monocyclic or polycyclic C₃₋₂₀ cycloalkyl, or monocyclic or polycyclic C₂₋₂₀ heterocycloalkyl;
L¹ is a divalent linking group comprising at least one carbon atom, at least one heteroatom, or a combination thereof;
R¹³ to R¹⁴ are each independently hydrogen, straight chain or branched C₁₋₂₀ alkyl, a monocyclic or polycyclic C₃₋₂₀ cycloalkyl, a monocyclic or polycyclic C₂₋₂₀ heterocycloalkyl, a monocyclic or polycyclic C₆₋₂₀ aryl, or a monocyclic or polycyclic C₁₋₂₀ heteroaryl, each of which except hydrogen is substituted or unsubstituted,
R¹⁵ is straight chain or branched C₁₋₂₀ alkyl, monocyclic or polycyclic C₃₋₂₀ cycloalkyl, or monocyclic or polycyclic C₂₋₂₀ heterocycloalkyl, each of which is substituted or unsubstituted, wherein one of R¹³ or R¹⁴ optionally forms a heterocyclic ring together with R¹⁵;
R¹⁶ to R¹⁸ are each independently straight chain or branched C₁₋₂₀ alkyl, a monocyclic or polycyclic C₃₋₂₀ cycloalkyl, a monocyclic or polycyclic C₂₋₂₀ heterocycloalkyl, a monocyclic or polycyclic C₆₋₂₀ aryl, or a monocyclic or polycyclic C₁₋₂₀ heteroaryl, each of which is substituted or unsubstituted;
any two of R¹⁶ to R¹⁸ together optionally form a ring, and each of R¹⁶ to R¹⁸ optionally further comprises as part of their structure one or more groups selected from —O—, —C(O)—, —C(O)—O—, —S—, —S(O)₂—, and —N(R²¹)—S(O)₂—, wherein R²¹ is hydrogen, a straight chain or branched C₁₋₂₀ alkyl, monocyclic or polycyclic C₃₋₂₀ cycloalkyl, or monocyclic or polycyclic C₂₋₂₀ heterocycloalkyl;
X^{a} is a polymerizable group selected from norbornyl and vinyl;
n is 0 or 1; and
L² is a single bond or a divalent linking group, provided that L² is not a single bond when X^{a} is vinyl.

6. The topcoat composition of claim 1, wherein the polymer further comprises a repeating unit derived from a monomer of formula (III), a monomer of formula (IV), or a combination thereof: 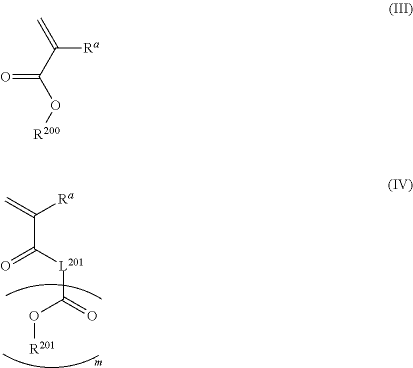
wherein,
R^{a} is hydrogen, fluorine, cyano, a substituted or unsubstituted C₁₋₁₀ alkyl, or a substituted or unsubstituted C₁₋₁₀ fluoroalkyl;
R²⁰⁰ is substituted or unsubstituted C₁₋₂₀ alkyl, substituted or unsubstituted C₃₋₃₀ cycloalkyl; or substituted or unsubstituted poly(C₁₋₃ alkylene oxide);
R²⁰¹ is linear, branched, or cyclic C₁₋₂₀ fluoroalkyl;
L²⁰¹ is a single bond or a multivalent linking group; and
m is an integer from 1 to 5

7. The topcoat composition of claim 1, wherein
a matrix polymer comprises the repeating unit derived from the one or more monomers of formula (1);
a surface active polymer comprises the repeating unit derived from the one or more monomers of formula (1);
or a combination thereof.

8. The topcoat composition of claim 1, further comprising a photoacid generator or a thermal acid generator.

9. A coated substrate, comprising:
a photoresist layer on a substrate; and
a topcoat layer formed on the photoresist layer, wherein the topcoat layer is derived from the topcoat composition of claim 1.

10. A pattern formation method, comprising:
forming a photoresist layer over a substrate;
forming a topcoat layer over the photoresist layer, wherein the topcoat layer is formed from a topcoat composition of claim 1;
pattern-wise exposing the topcoat layer and the photoresist layer to activating radiation; and
contacting the exposed topcoat layer and the exposed photoresist layer with a developer to form a resist pattern.

11. The method of claim 10, wherein the polymer comprises a repeating unit derived from one or more monomers of formula (1a): 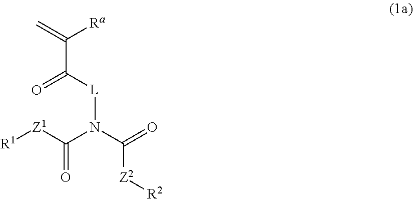
wherein,
R^{a} is hydrogen, fluorine, cyano, a substituted or unsubstituted C₁₋₁₀ alkyl, or a substituted or unsubstituted C₁₋₁₀ fluoroalkyl;
L is a single bond or a multivalent linking group;
optionally, L is a multivalent linking group further comprising an additional group of the formula: 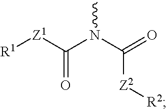
Z¹ and Z² are the same, wherein Z¹ and Z² are chosen from a single bond, —O—, a divalent linking group comprising a group of the formula —C(O)—, or a divalent linking group comprising a group of the formula —C(O)—O—;
R¹ and R² are each independently substituted or unsubstituted C₁₋₃₀ alkyl; and
optionally, R¹ and R² together form a ring via a single bond or a divalent linking group.

12. The method of claim 10, wherein, L is a single bond or a divalent linking group chosen from one or more of substituted or unsubstituted C₁₋₃₀ alkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted divalent C₇₋₃₀ arylalkyl, substituted or unsubstituted C₁₋₃₀ heteroarylene, or substituted or unsubstituted divalent C₂₋₃₀ heteroarylalkyl, —O—, —C(O)—, —C(O)—O—, —C(O)—N(R^{2b})—, —S—, —S(O)₂—, or —N(R^{2b})—S(O)₂-wherein R^{2b} is hydrogen, straight chain or branched C₁₋₂₀ alkyl, monocyclic or polycyclic C₃₋₂₀ cycloalkyl, or monocyclic or polycyclic C₂₋₂₀ heterocycloalkyl.

13. The method of claim 10, wherein
L is a group of the formula —C(O)-C₁₋₁₀ alkylene-O-;
Z¹ and Z² are each —O—; and
R¹ and R² are each independently substituted or unsubstituted C₁₋₃₀ alkyl.

14. The method of claim 10, further comprising a polymer having a repeating unit that is derived from one or more monomers of formulae (2a), (2b), (2c), (2d), or (2e): 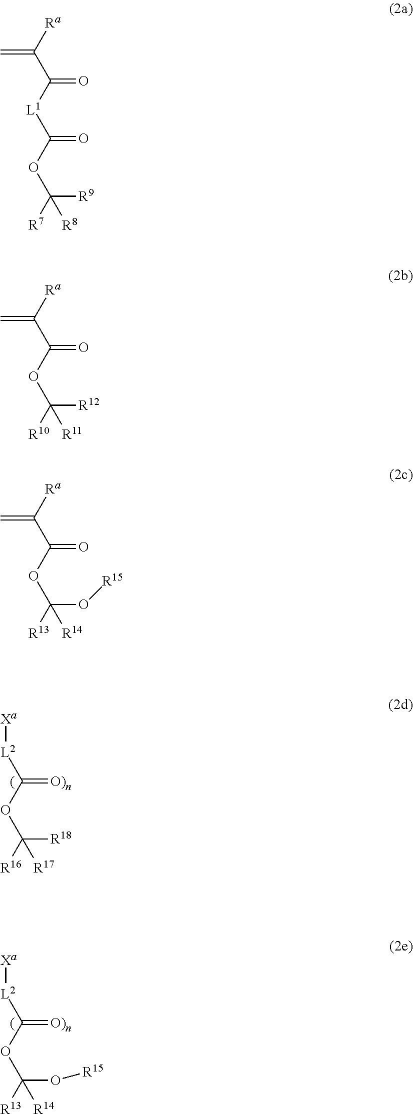
wherein,
R^{a} is hydrogen, fluorine, cyano, a substituted or unsubstituted C₁₋₁₀ alkyl, or a substituted or unsubstituted C₁₋₁₀ fluoroalkyl;
R⁷ to R¹² are each independently hydrogen, straight chain or branched C₁₋₂₀ alkyl, a monocyclic or polycyclic C₃₋₂₀ cycloalkyl, a monocyclic or polycyclic C₂₋₂₀ heterocycloalkyl, a straight chain or branched C₂₋₂₀ alkenyl, a monocyclic or polycyclic C₃₋₂₀ cycloalkenyl, a monocyclic or polycyclic C₃₋₂₀ heterocycloalkenyl, a monocyclic or polycyclic C₆₋₂₀ aryl, or a monocyclic or polycyclic C₁₋₂₀ heteroaryl, each of which is substituted or unsubstituted;
provided that only one of R⁷ to R⁹ can be hydrogen and only one of R¹⁰ to R¹² can be hydrogen;
any two of R⁷ to R⁹ together optionally form a ring, and each of R⁷ to R⁹ optionally further comprises as part of their structure one or more groups selected from —O—, —C(O)—, —C(O)—O—, —S—, —S(O)₂—, and —N(R¹⁹)—S(O)₂—, wherein R¹⁹ is hydrogen, a straight chain or branched C₁₋₂₀ alkyl, monocyclic or polycyclic C₃₋₂₀ cycloalkyl, or monocyclic or polycyclic C₂₋₂₀ heterocycloalkyl;
any two of R¹⁰ to R¹² together optionally form a ring, and each of R¹⁰ to R¹² optionally further comprises as part of their structure one or more groups selected from —O—, —C(O)—, —C(O)—O—, —S—, —S(O)₂—, and —N(R²⁰)—S(O)₂—, wherein R²⁰ is hydrogen, a straight chain or branched C₁₋₂₀ alkyl, monocyclic or polycyclic C₃₋₂₀ cycloalkyl, or monocyclic or polycyclic C₂₋₂₀ heterocycloalkyl;
L¹ is a divalent linking group comprising at least one carbon atom, at least one heteroatom, or a combination thereof;
R¹³ to R¹⁴ are each independently hydrogen, straight chain or branched C₁₋₂₀ alkyl, a monocyclic or polycyclic C₃₋₂₀ cycloalkyl, a monocyclic or polycyclic C₂₋₂₀ heterocycloalkyl, a monocyclic or polycyclic C₆₋₂₀ aryl, or a monocyclic or polycyclic C₁₋₂₀ heteroaryl, each of which except hydrogen is substituted or unsubstituted,
R¹⁵ is straight chain or branched C₁₋₂₀ alkyl, monocyclic or polycyclic C₃₋₂₀ cycloalkyl, or monocyclic or polycyclic C₂₋₂₀ heterocycloalkyl, each of which is substituted or unsubstituted, wherein one of R¹³ or R¹⁴ optionally forms a heterocyclic ring together with R¹⁵;
R¹⁶ to R¹⁸ are each independently straight chain or branched C₁₋₂₀ alkyl, a monocyclic or polycyclic C₃₋₂₀ cycloalkyl, a monocyclic or polycyclic C₂₋₂₀ heterocycloalkyl, a monocyclic or polycyclic C₆₋₂₀ aryl, or a monocyclic or polycyclic C₁₋₂₀ heteroaryl, each of which is substituted or unsubstituted;
any two of R¹⁶ to R¹⁸ together optionally form a ring, and each of R¹⁶ to R¹⁸ optionally further comprises as part of their structure one or more groups selected from —O—, —C(O)—, —C(O)—O—, —S—, —S(O)₂—, and —N(R²¹)—S(O)₂—, wherein R²¹ is hydrogen, a straight chain or branched C₁₋₂₀ alkyl, monocyclic or polycyclic C₃₋₂₀ cycloalkyl, or monocyclic or polycyclic C₂₋₂₀ heterocycloalkyl;
X^{a} is a polymerizable group selected from norbornyl and vinyl;
n is 0 or 1; and
L² is a single bond or a divalent linking group, provided that L² is not a single bond when X^{a} is vinyl.

15. The method of claim 10, wherein the polymer further comprises a repeating unit derived from a monomer of formula (III), a monomer of formula (IV), or a combination thereof: 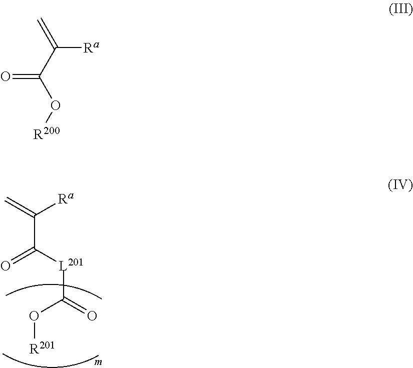
wherein,
R^{a} is hydrogen, fluorine, cyano, a substituted or unsubstituted C₁₋₁₀ alkyl, or a substituted or unsubstituted C₁₋₁₀ fluoroalkyl;
R²⁰⁰ is substituted or unsubstituted C₁₋₂₀ alkyl, substituted or unsubstituted C₃₋₃₀ cycloalkyl; or substituted or unsubstituted poly(C₁₋₃ alkylene oxide);
R²⁰¹ is linear, branched, or cyclic C₁₋₂₀ fluoroalkyl;
L²⁰¹ is a single bond or a multivalent linking group; and
m is an integer from 1 to 5

16. The method of claim 10, wherein
a matrix polymer comprises the repeating unit derived from the one or more monomers of formula (1);
a surface active polymer comprises the repeating unit derived from the one or more monomers of formula (1);
or a combination thereof.

17. The method of claim 10, further comprising a photoacid generator or a thermal acid generator.

18. The coated substrate of claim 9, wherein the polymer comprises a repeating unit derived from one or more monomers of formula (1a): 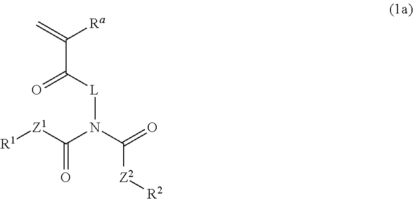
wherein,
R^{a} is hydrogen, fluorine, cyano, a substituted or unsubstituted C₁₋₁₀ alkyl, or a substituted or unsubstituted C₁₋₁₀ fluoroalkyl;
L is a single bond or a multivalent linking group;
optionally, L is a multivalent linking group further comprising an additional group of the formula: 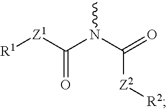
Z¹ and Z² are the same, wherein Z¹ and Z² are chosen from a single bond, —O—, a divalent linking group comprising a group of the formula —C(O)—, or a divalent linking group comprising a group of the formula —C(O)—O—;
R¹ and R² are each independently substituted or unsubstituted C₁₋₃₀ alkyl; and
optionally, R¹ and R² together form a ring via a single bond or a divalent linking group.

19. The coated substrate of claim 9, wherein,
L is a single bond or a divalent linking group chosen from one or more of substituted or unsubstituted C₁₋₃₀ alkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted divalent C₇₋₃₀ arylalkyl, substituted or unsubstituted C₁₋₃₀ heteroarylene, or substituted or unsubstituted divalent C₂₋₃₀ heteroarylalkyl, —O—, —C(O)—, —C(O)—O—, —C(O)—N(R^{2b})—, —S—, —S(O)₂—, or —N(R^{2b})—S(O)₂-wherein R^{2b} is hydrogen, straight chain or branched C₁₋₂₀ alkyl, monocyclic or polycyclic C₃₋₂₀ cycloalkyl, or monocyclic or polycyclic C₂₋₂₀ heterocycloalkyl.

20. The coated substrate of claim 9, further comprising a polymer having a repeating unit that is derived from one or more monomers of formulae (2a), (2b), (2c), (2d), or (2e): 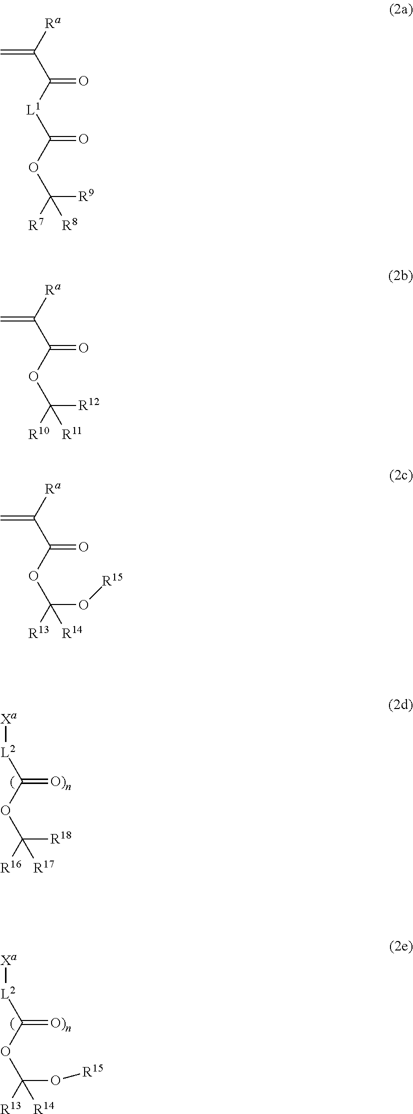
wherein,
R^{a} is hydrogen, fluorine, cyano, a substituted or unsubstituted C₁₋₁₀ alkyl, or a substituted or unsubstituted C₁₋₁₀ fluoroalkyl;
R⁷ to R′² are each independently hydrogen, straight chain or branched C₁₋₂₀ alkyl, a monocyclic or polycyclic C₃₋₂₀ cycloalkyl, a monocyclic or polycyclic C₂₋₂₀ heterocycloalkyl, a straight chain or branched C₂₋₂₀ alkenyl, a monocyclic or polycyclic C₃₋₂₀ cycloalkenyl, a monocyclic or polycyclic C₃₋₂₀ heterocycloalkenyl, a monocyclic or polycyclic C₆₋₂₀ aryl, or a monocyclic or polycyclic C₁₋₂₀ heteroaryl, each of which is substituted or unsubstituted;
provided that only one of R⁷ to R⁹ can be hydrogen and only one of R¹⁰ to R¹² can be hydrogen;
any two of R⁷ to R⁹ together optionally form a ring, and each of R⁷ to R⁹ optionally further comprises as part of their structure one or more groups selected from —O—, —C(O)—, —C(O)—O—, —S—, —S(O)₂—, and —N(R¹⁹)—S(O)₂—, wherein R¹⁹ is hydrogen, a straight chain or branched C₁₋₂₀ alkyl, monocyclic or polycyclic C₃₋₂₀ cycloalkyl, or monocyclic or polycyclic C₂₋₂₀ heterocycloalkyl;
any two of R¹⁰ to R¹² together optionally form a ring, and each of R¹⁰ to R¹² optionally further comprises as part of their structure one or more groups selected from —O—, —C(O)—, —C(O)—O—, —S—, —S(O)₂—, and —N(R²⁰)—S(O)₂—, wherein R²⁰ is hydrogen, a straight chain or branched C₁₋₂₀ alkyl, monocyclic or polycyclic C₃₋₂₀ cycloalkyl, or monocyclic or polycyclic C₂₋₂₀ heterocycloalkyl;
L¹ is a divalent linking group comprising at least one carbon atom, at least one heteroatom, or a combination thereof;
R¹³ to R¹⁴ are each independently hydrogen, straight chain or branched C₁₋₂₀ alkyl, a monocyclic or polycyclic C₃₋₂₀ cycloalkyl, a monocyclic or polycyclic C₂₋₂₀ heterocycloalkyl, a monocyclic or polycyclic C₆₋₂₀ aryl, or a monocyclic or polycyclic C₁₋₂₀ heteroaryl, each of which except hydrogen is substituted or unsubstituted,
R¹⁵ is straight chain or branched C₁₋₂₀ alkyl, monocyclic or polycyclic C₃₋₂₀ cycloalkyl, or monocyclic or polycyclic C₂₋₂₀ heterocycloalkyl, each of which is substituted or unsubstituted, wherein one of R¹³ or R¹⁴ optionally forms a heterocyclic ring together with R¹⁵;
R¹⁶ to R¹⁸ are each independently straight chain or branched C₁₋₂₀ alkyl, a monocyclic or polycyclic C₃₋₂₀ cycloalkyl, a monocyclic or polycyclic C₂₋₂₀ heterocycloalkyl, a monocyclic or polycyclic C₆₋₂₀ aryl, or a monocyclic or polycyclic C₁₋₂₀ heteroaryl, each of which is substituted or unsubstituted;
any two of R¹⁶ to R¹⁸ together optionally form a ring, and each of R¹⁶ to R¹⁸ optionally further comprises as part of their structure one or more groups selected from —O—, —C(O)—, —C(O)—O—, —S—, —S(O)₂—, and —N(R²¹)—S(O)₂—, wherein R²¹ is hydrogen, a straight chain or branched C₁₋₂₀ alkyl, monocyclic or polycyclic C₃₋₂₀ cycloalkyl, or monocyclic or polycyclic C₂₋₂₀ heterocycloalkyl;
X^{a} is a polymerizable group selected from norbornyl and vinyl;
n is 0 or 1; and
L² is a single bond or a divalent linking group, provided that L² is not a single bond when X^{a} is vinyl.
